(19) United States
(12) Patent Application Publication
(10) Pub. No.: US 2024/0332256 A1
(43) Pub. Date: Oct. 3, 2024

(54) SEMICONDUCTOR PACKAGE

(71) Applicant: Samsung Electronics Co., Ltd., Suwon-si (KR)

(72) Inventors: Jing Cheng LIN, Suwon-si (KR); Young Kun JEE, Suwon-si (KR)

(73) Assignee: Samsung Electronics Co., Ltd., Suwon-si (KR)

(21) Appl. No.: 18/382,807

(22) Filed: Oct. 23, 2023

(30) Foreign Application Priority Data
Mar. 29, 2023 (KR) 10-2023-0041227
May 26, 2023 (KR) 10-2023-0068585

(51) Int. Cl. H01L 25/065; H01L 23/00; H01L 23/31; H01L 23/538

(52) U.S. Cl. CPC H01L 25/0655; H01L 23/3128; H01L 23/5381; H01L 23/5383; H01L 24/16; H01L 2224/08145; H01L 2224/08225; H01L 2224/16145; H01L 2224/16227

(57) ABSTRACT

A semiconductor package includes a package substrate including a mounting region and an edge region at least partially surrounding the mounting region, a bridge chip on a top surface of the mounting region of the package substrate, a first connection pad and a second connection pad on the mounting region of the package substrate and spaced apart from the bridge chip, a third connection pad on the edge region of the package substrate, a first mold layer on the package substrate and at least partially surrounding the bridge chip, the first connection pad, the second connection pad and the third connection pad, a first semiconductor chip on the first connection pad and the bridge chip, a second semiconductor chip on the second connection pad and the bridge chip, and a conductive post on the third connection pad.

### CROSS-REFERENCE TO RELATED APPLICATIONS

This application is based on and claims priority to Korean Patent Application No. 10-2023-0068585, filed on May 26, 2023, in the Korean Intellectual Property Office, and Korean Patent Application No. 10-2023-0041227, filed on Mar. 29, 2023, in the Korean Intellectual Property Office, the disclosures of which are incorporated herein by reference in their entireties.

### BACKGROUND

Example embodiments of the disclosure relate to a semiconductor package and a method of fabricating the same, and in particular, to a semiconductor die including a bridge chip and a method of fabricating the same.

A semiconductor package may be configured to facilitate the use of an integrated circuit chip as a component in an electronic product. Typically, the semiconductor package may include a printed circuit board (PCB) and a semiconductor chip, which may be mounted on the PCB and may be electrically connected to the PCB by bonding wires or bumps. Due to recent advancements in the electronics industry, semiconductor packaging technology is being developed for miniaturization, weight reduction, and cost-effective manufacturing.

In light of recent advancements in the electronics industry, the demand for high-performance, high-speed, and compact electronic components has been steadily increasing. As a result, packaging technologies are developed that allow for the mounting of multiple semiconductor chips within a single package.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a semiconductor package with improved structural stability and a method of fabricating the same.

One or more example embodiments provide a compact semiconductor package and a method of fabricating the same.

One or more example embodiments provide a semiconductor package with improved electrical characteristics and a method of fabricating the same.

Additional aspects will be set forth in part in the description which follows and, in part, will be apparent from the description, or may be learned by practice of the presented embodiments.

According to an aspect of the disclosure, a semiconductor package may include a package substrate including a mounting region and an edge region at least partially surrounding the mounting region, a bridge chip on a top surface of the mounting region of the package substrate, a first connection pad and a second connection pad on the mounting region of the package substrate and spaced apart from the bridge chip, a third connection pad on the edge region of the package substrate, a first mold layer on the package substrate and at least partially surrounding the bridge chip, the first connection pad, the second connection pad and the third connection pad, a first semiconductor chip on the first connection pad and the bridge chip, a second semiconductor chip on the second connection pad and the bridge chip, a conductive post on the third connection pad, and a second mold layer on the first mold layer and at least partially surrounding the first semiconductor chip, the second semiconductor chip and the conductive post, where a first thermal expansion coefficient of the first mold layer is different from a second thermal expansion coefficient of the second mold layer.

According to an aspect of an example embodiment, a semiconductor package may include a package substrate, a bridge chip on the package substrate, the bridge chip including at least one first bridge chip pad and at least one second bridge chip pad on a top surface of the bridge chip and horizontally spaced apart, a first mold layer on the package substrate and at least partially surrounding the bridge chip, wherein the at least one first bridge chip pad and the at least one second bridge chip pad are exposed to an outside of the first mold layer, a plurality of first connection pads and a plurality of second connection pads horizontally spaced apart from the bridge chip, vertically penetrating the first mold layer, and coupled to the package substrate, the plurality of first connection pads being between the plurality of second connection pads, a first semiconductor chip on the first mold layer, and on first connection pads of the plurality of first connection pads and the at least one first bridge chip pad, a second semiconductor chip on the first mold layer, and on second connection pads of the plurality of first connection pads and the at least one second bridge chip pad, a second mold layer contacting the top surface of the first mold layer and at least partially surrounding the first semiconductor chip and the second semiconductor chip, a plurality of conductive posts vertically penetrating the second mold layer and respectively coupled to the plurality of second connection pads, and a plurality of outer terminals below the package substrate, where widths of the plurality of conductive posts are smaller than widths of the plurality of second connection pads.

According to an aspect of an example embodiment, a semiconductor package may include a package substrate, a device layer on the package substrate, and a connection layer between the package substrate and the device layer, where the device layer may include a first mold layer, a first semiconductor chip and a second semiconductor chip in the first mold layer, connection terminals provided on active surfaces of the first semiconductor chip and the second semiconductor chip and exposed to an outside of the first mold layer, and a conductive post vertically penetrating the first mold layer, where the connection layer may include a second mold layer, a bridge chip in the second mold layer, wherein each of the first semiconductor chip and the second semiconductor chip are positioned such that the active surfaces at least partially surround the bridge chip in a plan view, a plurality of first connection pads vertically penetrating the second mold layer and connecting the first semiconductor chip and the second semiconductor chip to the package substrate, and at least one second connection pad vertically penetrating the second mold layer and connecting the conductive post to the package substrate, where the connection terminals connect the first semiconductor chip and the second semiconductor chip to the bridge chip and a first thermal expansion coefficient of the first mold layer is different from a second thermal expansion coefficient of the second mold layer.

### BRIEF DESCRIPTION OF DRAWINGS

The above and other aspects, features, and advantages of certain example embodiments of the present disclosure will be more apparent from the following description taken in conjunction with the accompanying drawings, in which:

FIG. 1 is a cross-sectional view illustrating a semiconductor package according to an embodiment;

FIGS. 2 to 5 are enlarged cross-sectional views illustrating a portion ‘A’ of FIG. 1 according to some embodiments;

FIG. 6 is a cross-sectional view illustrating a semiconductor package according to an embodiment;

FIG. 7 is an enlarged cross-sectional view illustrating a portion ‘B’ of FIG. 6 according to an embodiment;

FIG. 8 is a cross-sectional view illustrating a semiconductor package according to an embodiment;

FIG. 9 is an enlarged cross-sectional view illustrating a portion ‘C’ of FIG. 8 according to an embodiment;

FIGS. 10 to 13 are cross-sectional views each illustrating a semiconductor package according to an embodiment;

FIGS. 14 to 21 are cross-sectional views illustrating a method of fabricating a semiconductor package, according to an embodiment;

FIGS. 22 to 25 are cross-sectional views illustrating a method of fabricating a semiconductor package, according to an embodiment of the disclosure; and

FIGS. 26 to 28 are cross-sectional views illustrating a method of fabricating a semiconductor package, according to an embodiment of the disclosure.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

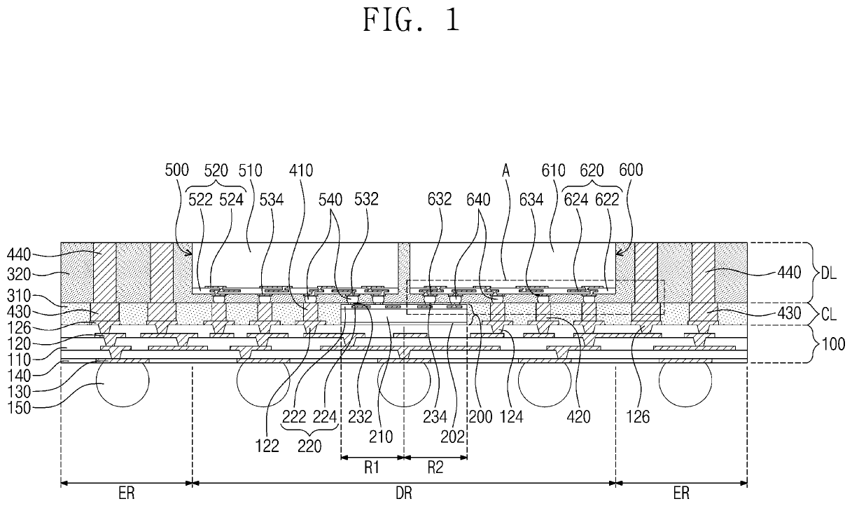

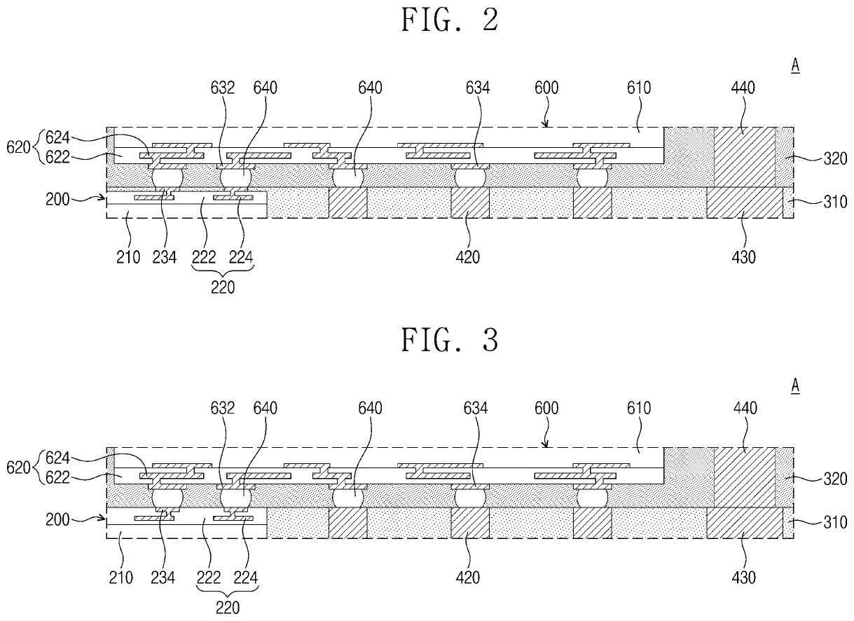

FIG. 1 is a cross-sectional view illustrating a semiconductor package according to an embodiment. FIGS. 2 to 5 are enlarged cross-sectional views illustrating a portion ‘A’ of FIG. 1 according to embodiments. That is, FIGS. 2 to 5 show various example embodiments of the portion ‘A’ of FIG. 1.

Referring to FIGS. 1 and 2, a semiconductor package may include a package substrate 100, a device layer DL on the package substrate 100, and a connection layer CL between the package substrate 100 and the device layer DL.

The package substrate 100 may be provided. The package substrate 100 may have a mounting region DR and an edge region ER. The mounting region DR may be placed on a center portion of the package substrate 100. In a plan view, the edge region ER may be provided to surround or at least partially surround the mounting region DR. The mounting region DR may be defined as a region, on which a bridge chip 200, a first semiconductor chip 500, and a second semiconductor chip 600 of the semiconductor package are disposed. The edge region ER may be defined as an extra region or outer region of the package substrate 100, in which the bridge chip 200 and the first and second semiconductor chips 500 and 600 are not provided.

The package substrate 100 may be a redistribution substrate. For example, the package substrate 100 may include one or more first substrate interconnection layers, which are sequentially stacked. Each of the first substrate interconnection layers may include a first substrate insulating pattern 110 and a first substrate interconnection pattern 120 in the first substrate insulating pattern 110. The first substrate interconnection pattern 120 of one of the first substrate interconnection layers may be electrically connected to the first substrate interconnection pattern 120 of a neighboring one of the first substrate interconnection layers.

The first substrate insulating pattern 110 may be formed of or include at least one of insulating polymers and photoimageable polymers (e.g., photoimageable dielectric (PID) materials). For example, the photoimageable polymers may include at least one of photoimageable polyimide (PI), polybenzoxazole (PBO), phenol-based polymers, and benzocyclobutene-based polymers. Alternatively, the first substrate insulating pattern 110 may be formed of or include at least one insulating material. For example, the first substrate insulating pattern 110 may be formed of or include at least one of silicon oxide (SiO), silicon nitride (SiN), silicon oxynitride (SiON), and insulating polymers.

The first substrate interconnection pattern 120 may be provided on the first substrate insulating pattern 110. The first substrate interconnection pattern 120 may be horizontally extended, on the first substrate insulating pattern 110. The first substrate interconnection pattern 120 may be provided on a top surface of the first substrate insulating pattern 110. The first substrate interconnection pattern 120 may extend above the top surface of the first substrate insulating pattern 110. The first substrate interconnection pattern 120 on the first substrate insulating pattern 110 may be covered or at least partially covered with another substrate insulating pattern thereon. The first substrate interconnection pattern 120, which may be provided in the uppermost one of the first substrate interconnection layers, may be used as substrate pads, which are coupled to first to third connection pads 410, 420, and 430 to be described below. For example, the first substrate interconnection pattern 120, which may be provided in the uppermost one of the first substrate interconnection layers, may include portions, which are used as first substrate pads 122 coupled to the first connection pads 410, second substrate pads 124 coupled to the second connection pads 420, and third substrate pads 126 coupled to the third connection pads 430. The first and second substrate pads 122 and 124 may be placed on the mounting region DR, and the third substrate pads 126 may be placed on the edge region ER. As described above, the first substrate interconnection pattern 120 may serve as a pad portion or a wire portion of the first substrate interconnection layer. In other words, the first substrate interconnection pattern 120 may be an element for horizontal redistribution of the package substrate 100. The first substrate interconnection pattern 120 may be formed of or include at least one of conductive materials. For example, the first substrate interconnection pattern 120 may be formed of or include at least one of metallic materials (e.g., copper (Cu)).

The first substrate interconnection pattern 120 may have a damascene structure. For example, the first substrate interconnection pattern 120 may include a via portion extending toward a bottom surface thereof. The via portion may be configured to vertically connect the first substrate interconnection patterns 120 (which are included in adjacent ones of the first substrate interconnection layers) to each other. For example, the via portion may extend from the bottom surface of the first substrate interconnection pattern 120 to penetrate the first substrate insulating pattern 110 and may be coupled to a top surface of the first substrate interconnection pattern 120 of another first substrate interconnection layer thereunder. In an embodiment, the via portion may be configured to connect the first substrate interconnection pattern 120 of the lowermost one of the first substrate interconnection layers to outer pads 130. For example, the via portion may extend from the bottom surface of the first substrate interconnection pattern 120 to penetrate the lowermost one of the first substrate insulating patterns 110 and may be coupled to top surfaces of the outer pads 130. In other words, an upper portion of the first substrate interconnection pattern 120, which is placed on the first substrate insulating pattern 110, may be a head portion serving as a horizontal wire or a pad, and the via portion of the first substrate interconnection pattern 120 may be a tail portion. The first substrate interconnection pattern 120 may be a ‘T’-shaped pattern.

The outer pads 130 may be provided on a bottom surface of the lowermost one of the first substrate interconnection layers. The outer pads 130 may be electrically connected to the first substrate interconnection pattern 120. The outer pads 130 may be coupled to outer terminals 150.

A substrate protection layer 140 may be provided. The substrate protection layer 140 may be provided to cover or at least partially cover the bottom surface of the lowermost one of the first substrate interconnection layers and expose the outer pads 130. The substrate protection layer 140 may be formed of or include at least one of insulating polymers and photoimageable polymers (e.g., PID materials). The outer terminals 150 may be provided on the exposed bottom surfaces of the outer pads 130. The outer terminals 150 may include solder balls or solder bumps. The semiconductor package may include solder balls or solder bumps, and the semiconductor package may be classified into a ball grid array (BGA) package, a fine ball-grid array (FBGA) package, or a land grid array (LGA) package, depending on the kind and arrangement of the outer terminals 150.

In an embodiment, the package substrate 100 may be provided to have the afore-described structure. However, the disclosure is not limited to this example. The package substrate 100 may be a printed circuit board (PCB). For example, the package substrate 100 may include a core layer and peripheral portions, which are provided on and under the core layer and are used for interconnection.

The bridge chip 200 may be disposed on the package substrate 100. The bridge chip 200 may be disposed on the mounting region DR. The bridge chip 200 may contact a top surface of the package substrate 100. The bridge chip 200 may have a front surface and a rear surface. Hereinafter, the front surface may be defined as a surface of a semiconductor chip, which is an active surface for integrated devices, and on which interconnection wires or pads are formed, and the rear surface may be defined as a surface that is opposite to the front surface of the semiconductor chip. The rear surface of the bridge chip 200 may face the package substrate 100. In other words, the bridge chip 200 may be disposed on the package substrate 100 in a face-up manner. The bridge chip 200 may be attached to the package substrate 100 using an adhesive layer 202. For example, the adhesive layer 202 may be interposed between the bottom surface of the bridge chip 200 and the top surface of the package substrate 100. In an embodiment, any pad used as the substrate pad of the package substrate 100 may not be provided under the bridge chip 200. The bridge chip 200 may have a first region R1 and a second region R2, which are horizontally spaced apart from each other. The first region R1 may be overlapped by the first semiconductor chip 500, and the second region R2 may be overlapped by the second semiconductor chip 600. The bridge chip 200 may include a bridge base layer 210 and a bridge interconnection layer 220.

The bridge base layer 210 may include a semiconductor substrate. For example, the bridge base layer 210 may be a semiconductor substrate (e.g., a semiconductor wafer). The bridge base layer 210 may be a silicon substrate, a silicon-on-insulator (SOI) substrate, a germanium substrate, a germanium-on-insulator (GOI) substrate, a silicon-germanium substrate, a group III-V semiconductor substrate, or a substrate including an epitaxial film formed by a selective epitaxial growth (SEG) process. The bridge base layer 210 may be formed of or include at least one of silicon (Si), germanium (Ge), silicon-germanium (SiGe), gallium arsenic (GaAs), indium gallium arsenic (InGaAs), and aluminum gallium arsenic (AlGaAs).

The bridge interconnection layer 220 may be disposed on a top surface of the bridge base layer 210. For example, the bridge interconnection layer 220 may include a bridge insulating pattern 222 and a bridge interconnection pattern 224, which are formed on the top surface of the bridge base layer 210. The bridge interconnection layer 220 may further include a circuit pattern or a protection layer, if necessary.

The bridge insulating pattern 222 may be formed of or include at least one insulating material. For example, the bridge insulating pattern 222 may be formed of or include at least one of silicon oxide (SiO), silicon nitride (SiN), silicon oxynitride (SiON), silicon carbonitride (SiCN), and insulating polymers. Alternatively, the bridge insulating pattern 222 may be formed of or include at least one of insulating polymers and photoimageable polymers (e.g., PID materials). For example, the photoimageable polymers may include at least one of PI, PBO, phenol-based polymers, or benzocyclobutene-based polymers.

The bridge interconnection pattern 224 may be provided in the bridge insulating pattern 222. The bridge interconnection pattern 224 may be an element which is used for an electrical connection between the first semiconductor chip 500 and the second semiconductor chip 600. The bridge interconnection pattern 224 may be formed of or include at least one conductive material. For example, the bridge interconnection pattern 224 may be formed of or include at least one metallic material (e.g., copper (Cu) or aluminum (Al)).

FIGS. 1 and 2 illustrate an example in which the bridge insulating pattern 222 is provided in the form of a single layer, but the disclosure is not limited to this example. The bridge insulating pattern 222 may include a plurality of insulating layers, and the bridge interconnection pattern 224 may be an interconnection pattern provided in the insulating layers.

The bridge chip 200 may include first bridge chip pads 232 and second bridge chip pads 234, which are provided on a top surface of the bridge chip 200. The first and second bridge chip pads 232 and 234 may be disposed on the top surface of the bridge chip 200 (i.e., the top surface of the bridge interconnection layer 220). In an embodiment, the first and second bridge chip pads 232 and 234 may be protruding portions that are extended to a level higher than the top surface of the bridge chip 200. However, the disclosure is not limited to this example, and the first and second bridge chip pads 232 and 234 may be portions of the bridge interconnection pattern 224 and may be provided in the bridge insulating pattern 222. In this case, the first and second bridge chip pads 232 and 234 may be exposed to the outside of the bridge insulating pattern 222 near the top surface of the bridge insulating pattern 222.

The first bridge chip pads 232 may be disposed on the first region R1. The second bridge chip pads 234 may be disposed on the second region R2. The first bridge chip pads 232 may be electrically connected to the first semiconductor chip 500, and the second bridge chip pads 234 may be electrically connected to the second semiconductor chip 600. The first bridge chip pads 232 may be electrically connected to the second bridge chip pads 234 through the bridge interconnection layer 220. FIGS. 1 and 2 only illustrate a portion of the bridge interconnection pattern 224, and as such, various aspects may not be explicitly shown (e.g., the first bridge chip pads 232 in the bridge interconnection layer 220 may not be electrically disconnected from the second bridge chip pads 234 may not be in an electrically floated state). The first bridge chip pads 232 may be electrically connected to the second bridge chip pads 234 through the bridge interconnection pattern 224 in the bridge interconnection layer 220.

The first and second connection pads 410 and 420 may be disposed on the package substrate 100. The first and second connection pads 410 and 420 may be horizontally spaced apart from the bridge chip 200, on the mounting region DR. The first connection pads 410 may be disposed adjacent to the first region R1 of the bridge chip 200, and the second connection pads 420 may be disposed adjacent to the second region R2 of the bridge chip 200. The first connection pads 410 may be disposed on the first substrate pads 122. Each of the first connection pads 410 may contact a top surface of one of the first substrate pads 122. The first connection pads 410 may be configured to connect the first semiconductor chip 500 to the package substrate 100. The second connection pads 420 may be disposed on the second substrate pads 124. Each of the second connection pads 420 may contact a top surface of one of the second substrate pads 124. The second connection pads 420 may be configured to connect the second semiconductor chip 600 to the package substrate 100. In other words, the first and second connection pads 410 and 420 may correspond to a vertical connection terminal. The first and second connection pads 410 and 420 may have a vertically-extended pillar shape. For example, the first and second connection pads 410 and 420 may be conductive posts. However, the disclosure is not limited to this example, and the first and second connection pads 410 and 420 may be provided in various shapes which can be used as pads. Top surfaces of the first and second connection pads 410 and 420 and top surfaces of the first and second bridge chip pads 232 and 234 of the bridge chip 200 may be located on the same plane. The first and second connection pads 410 and 420 may be formed of or include at least one conductive material. For example, the first and second connection pads 410 and 420 may be formed of or include at least one metallic material (e.g., copper (Cu) or tungsten (W)).

The third connection pads 430 may be disposed on the package substrate 100. The third connection pads 430 may be disposed in the edge region ER. For example, the first and second connection pads 410 and 420 may be placed between the third connection pads 430 and the bridge chip 200. The third connection pads 430 may be disposed on the third substrate pads 126. Each of the third connection pads 430 may contact a top surface of one of the third substrate pads 126. The third connection pads 430 may be configured to connect the package substrate 100 to conductive posts 440, which will be described below. In an embodiment, the third connection pads 430 may correspond to a vertical connection terminal. The third connection pads 430 may have a vertically-extended pillar shape. For example, the third connection pads 430 may be conductive posts. However, the disclosure is not limited to this example, the third connection pads 430 may be provided in various shapes which can be used as pads. Widths of the third connection pads 430 may be larger than widths of the first and second connection pads 410 and 420. In The first and second connection pads 410 and 420 may be connected to the first and second semiconductor chips 500 and 600, in which interconnection patterns are provided in a high integration density, and in this case, the width and pitch of the first and second connection pads 410 and 420 may be smaller than the width and pitch of the third connection pads 430 connecting the package substrate 100 to the conductive posts 440. Top surfaces of the third connection pads 430 and top surfaces of the first and second bridge chip pads 232 and 234 of the bridge chip 200 may be located on the same plane. The third connection pads 430 may be formed of or include at least one conductive material. For example, the third connection pads 430 may be formed of or include at least one metallic material (e.g., copper (Cu) or tungsten (W)).

A first mold layer 310 may be provided on the package substrate 100. The first mold layer 310 may be provided on the package substrate 100 to surround or at least partially surround the bridge chip 200 and the first to third connection pads 410, 420, and 430. The first mold layer 310 may cover or at least partially cover the bridge interconnection layer 220 of the bridge chip 200. The first mold layer 310 may be provided to surround or at least partially surround the first and second bridge chip pads 232 and 234 of the bridge chip 200. The first and second bridge chip pads 232 and 234 may not be covered with the first mold layer 310 and may be exposed to the outside of the first mold layer 310 near the top surface of the first mold layer 310. The top surface of the first mold layer 310, the top surfaces of the first and second bridge chip pads 232 and 234, and the top surfaces of the first to third connection pads 410, 420, and 430 may be substantially flat and may be substantially coplanar with each other. The first mold layer 310 may be formed of or include at least one insulating material. For example, the first mold layer 310 may be formed of or include an insulating polymer material (e.g., an epoxy molding compound (EMC)). Alternatively, the first mold layer 310 may be formed of or include at least one insulating material (e.g., silicon oxide (SiO), silicon nitride (SiN), and silicon oxynitride (SiON)).

The first mold layer 310, the bridge chip 200, and the first to third connection pads 410, 420, and 430 may constitute the connection layer CL, which may be provided in the form of a single layer. The connection layer CL may be configured to enable an electrical connection between the package substrate 100 and the device layer DL and redistribution of the package substrate 100 or the device layer DL.

The device layer DL may be provided on the connection layer CL. The device layer DL may include the first and second semiconductor chips 500 and 600, the conductive posts 440, and a second mold layer 320.

FIG. 2 illustrates an example, in which the first and second bridge chip pads 232 and 234 of the bridge chip 200 are placed at a level higher than the top surface of the bridge interconnection layer 220 and the first mold layer 310 is provided to cover or at least partially cover the top surface of the bridge interconnection layer 220, but the disclosure is not limited to this example. As shown in FIG. 3, the first and second bridge chip pads 232 and 234 may be buried in the bridge interconnection layer 220. For example, the first and second bridge chip pads 232 and 234 may be portions of the bridge interconnection pattern 224 of the bridge interconnection layer 220, which is exposed to the outside of the bridge interconnection layer 220. A top surface of the bridge insulating pattern 222 and top surfaces of the first and second bridge chip pads 232 and 234 may be substantially flat and may be substantially coplanar with each other. In this case, the first mold layer 310 may not cover the top surface of the bridge chip 200. The top surface of the first mold layer 310 may be coplanar with the top surface of the bridge chip 200. The following description will be given based on the embodiment of FIG. 2.

Referring back to FIGS. 1 and 2, the first semiconductor chip 500 may be provided on the first mold layer 310. A portion of the first semiconductor chip 500 may vertically overlap the first region R1 of the bridge chip 200. For example, the first semiconductor chip 500 may be placed on the first region R1 of the bridge chip 200 and may be horizontally shifted from the bridge chip 200. In other words, the bridge chip 200 and the first semiconductor chip 500 may be disposed to form an offset stacking structure. The portion of the first semiconductor chip 500 may be placed on the first region R1 of the bridge chip 200, and a remaining portion of the first semiconductor chip 500 may be placed on a region beside the bridge chip 200. The remaining portion of the first semiconductor chip 500 may be placed on the first connection pads 410. When the semiconductor package is viewed from its bottom surface, a bottom surface of the first semiconductor chip 500 may have an exposed portion that is not covered by the bridge chip 200. The first semiconductor chip 500 may include a first chip base layer 510 and a first chip interconnection layer 520.

The first chip base layer 510 may include a semiconductor substrate. For example, the first chip base layer 510 may be a semiconductor substrate (e.g., a semiconductor wafer). The first chip base layer 510 may be a silicon substrate, a SOI substrate, a germanium substrate, a GOI substrate, a silicon-germanium substrate, a group III-V semiconductor substrate, or a substrate including an epitaxial film formed by a SEG process. The first chip base layer 510 may be formed of or include at least one of silicon (Si), germanium (Ge), silicon-germanium (SiGe), gallium arsenic (GaAs), indium gallium arsenic (InGaAs), or aluminum gallium arsenic (AlGaAs). A first integrated circuit may be provided on a bottom surface of the first chip base layer 510. The first integrated circuit may include a logic circuit or a memory circuit. For example, the first semiconductor chip 500 may be a logic chip or a memory chip. However, the disclosure is not limited to this example, and the first semiconductor chip 500 may include a logic chip, a memory chip, a semiconductor chip with other integrated circuit, or a passive device. The bottom surface of the first semiconductor chip 500 may be an active surface, and the top surface of the first semiconductor chip 500 may be an inactive surface. In an embodiment, the first semiconductor chip 500 may be disposed on the first mold layer 310 in a face-down manner.

The first chip interconnection layer 520 may be disposed on the bottom surface of the first chip base layer 510. For example, the first chip interconnection layer 520 may include a first chip insulating pattern 522 and a first chip interconnection pattern 524, which are formed on the bottom surface of the first chip base layer 510. The first chip interconnection layer 520 may further include a circuit pattern or a protection layer.

The first chip insulating pattern 522 may be disposed on the bottom surface of the first chip base layer 510 to cover or at least partially cover the first integrated circuit. The first chip insulating pattern 522 may be formed of or include at least one insulating material. For example, the first chip insulating pattern 522 may be formed of or include at least one of silicon oxide (SiO), silicon nitride (SiN), silicon oxynitride (SiON), silicon carbonitride (SiCN), and insulating polymers. Alternatively, the first chip insulating pattern 522 may be formed of or include at least one of insulating polymers and photoimageable polymers (e.g., PID materials). For example, the photoimageable polymers may include at least one of PI, PBO, phenol-based polymers, and benzocyclobutene-based polymers.

The first chip interconnection pattern 524 may be provided in the first chip insulating pattern 522. The first chip interconnection pattern 524 may be electrically connected to the first integrated circuit, which is formed on the bottom surface of the first chip base layer 510. The first chip interconnection pattern 524 may be formed of or include at least one conductive material. For example, the first chip interconnection pattern 524 may be formed of or include copper (Cu) or aluminum (Al).

FIG. 1 illustrates an example, in which the first chip insulating pattern 522 is provided in the form of a single layer, but the disclosure is not limited to this example. For example, the first chip insulating pattern 522 may include a plurality of insulating layers, and the first chip interconnection pattern 524 may be an interconnection pattern, which is provided in the insulating layers.

The first semiconductor chip 500 may include first semiconductor chip pads 532 and second semiconductor chip pads 534, which are provided on the bottom surface of the first semiconductor chip 500. The first and second semiconductor chip pads 532 and 534 may be disposed on the bottom surface of the first semiconductor chip 500 (i.e., the bottom surface of the first chip interconnection layer 520). In other words, the first and second semiconductor chip pads 532 and 534 may be exposed to the outside of the first semiconductor chip 500 near the bottom surface of the first semiconductor chip 500. The first and second semiconductor chip pads 532 and 534 may be electrically connected to the first integrated circuit, which is formed on the bottom surface of the first chip base layer 510, through the first chip insulating pattern 522 in the first chip interconnection layer 520.

The first semiconductor chip pads 532 may be provided between the first semiconductor chip 500 and the bridge chip 200. The first semiconductor chip pads 532 may be disposed on a region of the bottom surface of the first semiconductor chip 500 facing the first region R1 of the bridge chip 200. The second semiconductor chip pads 534 may be provided between the first semiconductor chip 500 and the first connection pads 410. The second semiconductor chip pads 534 may be disposed on another region of the bottom surface of the first semiconductor chip 500 facing the first connection pads 410. The first semiconductor chip pads 532 may be electrically connected to the first bridge chip pads 232 of the bridge chip 200, and the second semiconductor chip pads 534 may be electrically connected to the first connection pads 410.

The first semiconductor chip 500 may be mounted on the bridge chip 200 and the first connection pads 410. For example, the first semiconductor chip 500 may be mounted on the bridge chip 200 and the first connection pads 410 in a flip-chip manner. The first semiconductor chip 500 may be electrically connected to the bridge chip 200 and the first connection pads 410 through first connection terminals 540. The first connection terminals 540 may be provided between the first bridge chip pads 232 and the first semiconductor chip pads 532 and between the first connection pads 410 and the second semiconductor chip pads 534. The first semiconductor chip 500 may be electrically connected to the bridge chip 200 through the first semiconductor chip pads 532, the first connection terminals 540, and the first bridge chip pads 232 and may be electrically connected to the package substrate 100 through the second semiconductor chip pads 534, the first connection terminals 540, and the first connection pads 410. Since the first semiconductor chip 500 is mounted using the first connection terminals 540, the first semiconductor chip 500 may be spaced apart from the top surface of the first mold layer 310, the top surface of the bridge chip 200, and the top surfaces of the first connection pads 410.

The second semiconductor chip 600 may be provided on the first mold layer 310. The second semiconductor chip 600 may be disposed to be horizontally spaced apart from the first semiconductor chip 500. A portion of the second semiconductor chip 600 may vertically overlap the second region R2 of the bridge chip 200. For example, the second semiconductor chip 600 may be placed on the second region R2 of the bridge chip 200 and may be horizontally shifted from the bridge chip 200. In other words, the bridge chip 200 and the second semiconductor chip 600 may be disposed to form an offset stacking structure. The portion of the second semiconductor chip 600 may be placed on the second region R2 of the bridge chip 200, and a remaining portion of the second semiconductor chip 600 may be placed on a region beside the bridge chip 200. The remaining portion of the second semiconductor chip 600 may be placed on the second connection pads 420. When the semiconductor package is viewed from its bottom surface, a bottom surface of the second semiconductor chip 600 may have an exposed portion that is not covered by the bridge chip 200. The second semiconductor chip 600 may include a second chip base layer 610 and a second chip interconnection layer 620.

The second chip base layer 610 may include a semiconductor substrate. For example, the second chip base layer 610 may be a semiconductor substrate (e.g., a semiconductor wafer). The second chip base layer 610 may be a silicon substrate, a SOI substrate, a germanium substrate, a GOI substrate, a silicon-germanium substrate, a group III-V semiconductor substrate, or a substrate including an epitaxial film formed by a SEG process. The second chip base layer 610 may be formed of or include at least one of silicon (Si), germanium (Ge), silicon-germanium (SiGe), gallium arsenic (GaAs), indium gallium arsenic (InGaAs), and aluminum gallium arsenic (AlGaAs). A second integrated circuit may be provided on a bottom surface of the second chip base layer 610. The second integrated circuit may include a logic circuit or a memory circuit. In other words, the second semiconductor chip 600 may be a logic chip or a memory chip. However, the disclosure is not limited to this example, and the second semiconductor chip 600 may include a logic chip, a memory chip, a semiconductor chip with other integrated circuit, or a passive device. The second semiconductor chip 600 may be of the same kind as or a different kind from the first semiconductor chip 500. The bottom surface of the second semiconductor chip 600 may be an active surface, and the top surface of the second semiconductor chip 600 may be an inactive surface. In an embodiment, the second semiconductor chip 600 may be disposed on the first mold layer 310 in a face-down manner.

The second chip interconnection layer 620 may be disposed on the bottom surface of the second chip base layer 610. For example, the second chip interconnection layer 620 may include a second chip insulating pattern 622 and a second chip interconnection pattern 624, which are formed on the bottom surface of the second chip base layer 610. The second chip interconnection layer 620 may further include a circuit pattern or a protection layer, if necessary.

The second chip insulating pattern 622 may be disposed on the bottom surface of the second chip base layer 610 to cover or at least partially cover the second integrated circuit. The second chip insulating pattern 622 may be formed of or include at least one insulating material. For example, the second chip insulating pattern 622 may be formed of or include at least one of silicon oxide (SiO), silicon nitride (SiN), silicon oxynitride (SiON), silicon carbonitride (SiCN), and insulating polymers. Alternatively, the second chip insulating pattern 622 may be formed of or include at least one of insulating polymers and photoimageable polymers (e.g., PID materials). For example, the photoimageable polymers may include at least one of PI, PBO, phenol-based polymers, or benzocyclobutene-based polymers.

The second chip interconnection pattern 624 may be provided in the second chip insulating pattern 622. The second chip interconnection pattern 624 may be electrically connected to the second integrated circuit, which is formed on the bottom surface of the second chip base layer 610. The second chip interconnection pattern 624 may be formed of or include at least one conductive material. For example, the second chip interconnection pattern 624 may be formed of or include copper (Cu) or aluminum (Al).

FIG. 1 illustrates an example, in which the second chip insulating pattern 622 is provided in the form of a single layer, but the disclosure is not limited to this example. The second chip insulating pattern 622 may include a plurality of insulating layers, and the second chip interconnection pattern 624 may be an interconnection pattern, which is provided in the insulating layers.

The second semiconductor chip 600 may include third semiconductor chip pads 632 and fourth semiconductor chip pads 634, which are provided on the bottom surface of the second semiconductor chip 600. The third and fourth semiconductor chip pads 632 and 634 may be disposed on the bottom surface of the second semiconductor chip 600 (i.e., a bottom surface of the second chip interconnection layer 620). For example, the third and fourth semiconductor chip pads 632 and 634 may be exposed to the outside of the second semiconductor chip 600 near the bottom surface of the second semiconductor chip 600. The third and fourth semiconductor chip pads 632 and 634 may be electrically connected to the second integrated circuit, which is formed on the bottom surface of the second chip base layer 610, through the second chip insulating pattern 622 in the second chip interconnection layer 620.

The third semiconductor chip pads 632 may be provided between the second semiconductor chip 600 and the bridge chip 200. The third semiconductor chip pads 632 may be disposed on a region of the bottom surface of the second semiconductor chip 600 facing the second region R2 of the bridge chip 200. The fourth semiconductor chip pads 634 may be provided between the second semiconductor chip 600 and the second connection pads 420. The fourth semiconductor chip pads 634 may be disposed on another region of the bottom surface of the second semiconductor chip 600 facing the second connection pads 420. The third semiconductor chip pads 632 may be electrically connected to the second bridge chip pads 234 of the bridge chip 200, and the fourth semiconductor chip pads 634 may be connected to the second connection pads 420.

The second semiconductor chip 600 may be mounted on the bridge chip 200 and the second connection pads 420. For example, the second semiconductor chip 600 may be mounted on the bridge chip 200 and the second connection pads 420 in a flip-chip manner. The second semiconductor chip 600 may be electrically connected to the bridge chip 200 and the second connection pads 420 through second connection terminals 640. The second connection terminals 640 may be provided between the second bridge chip pads 234 and the third semiconductor chip pads 632 and between the second connection pads 420 and the fourth semiconductor chip pads 634. The second semiconductor chip 600 may be electrically connected to the bridge chip 200 through the third semiconductor chip pads 632, the second connection terminals 640, and the second bridge chip pads 234 and may be electrically connected to the package substrate 100 through the fourth semiconductor chip pads 634, the second connection terminals 640, and the second connection pads 420. Since the second semiconductor chip 600 is mounted using the second connection terminals 640, the second semiconductor chip 600 may be spaced apart from the top surface of the first mold layer 310, the top surface of the bridge chip 200, and the top surfaces of the third connection pads 430.

The bridge chip 200 may electrically connect the first semiconductor chip 500 to the second semiconductor chip 600. For example, the first semiconductor chip 500 may be connected to the second semiconductor chip 600 through the first semiconductor chip pads 532, the first connection terminals 540, the first bridge chip pads 232, the bridge chip 200, the second bridge chip pads 234, the third semiconductor chip pads 632, and the second connection terminals 640.

According to an embodiment of the disclosure, the first and second semiconductor chips 500 and 600 may be directly mounted on the bridge chip 200, without an intermediate substrate. In an embodiment, the first and second semiconductor chips 500 and 600 and the bridge chip 200 may be disposed in a face-to-face manner, and in this case, the lengths of electrical connection paths between the first and second semiconductor chips 500 and 600 and the bridge chip 200 and between the first and second semiconductor chips 500 and 600 may be reduced. Electrical characteristics of the semiconductor package may thus be improved. In addition, the bridge chip 200 and the first and second connection pads 410 and 420 may constitute the connection layer CL, which is provided in the form of a single layer, using the first mold layer 310. A thickness of the connection layer CL and a size of the semiconductor package may be reduced to improve structural stability of the semiconductor package.

The second mold layer 320 may be provided on the first mold layer 310. The second mold layer 320 on the first mold layer 310 may be provided to surround or at least partially surround the first and second semiconductor chips 500 and 600. In an embodiment, the second mold layer 320 may be provided to expose the top surface of the first semiconductor chip 500 and the top surface of the second semiconductor chip 600. Alternatively, the first and second semiconductor chips 500 and 600 may be covered or at least partially covered with the second mold layer 320. In an embodiment, the second mold layer 320 may be provided to fill or at least partially fill a space between the first semiconductor chip 500 and the first mold layer 310 and a space between the second semiconductor chip 600 and the first mold layer 310. The second mold layer 320 below the first semiconductor chip 500 may surround or at least partially surround the first connection terminals 540, and the second mold layer 320 below the second semiconductor chip 600 may surround or at least partially surround the second connection terminals 640. The second mold layer 320 may be formed of or include at least one insulating material. For example, the second mold layer 320 may be formed of or include an insulating polymer material (e.g., an EMC).

A thermal expansion coefficient of the second mold layer 320 may be different from a thermal expansion coefficient of the first mold layer 310. For example, the thermal expansion coefficient of the second mold layer 320 may be smaller than the thermal expansion coefficient of the first mold layer 310.

The semiconductor package may suffer from a warpage issue, which is caused by heat energy that is supplied or generated in a process of fabricating or operating the semiconductor package. According to an embodiment of the disclosure, a mold layer on the package substrate 100 may be composed of lower and upper mold layers (e.g., the first and second mold layers 310 and 320) having different thermal expansion coefficients from each other. The thermal expansion coefficient of the second mold layer 320 may be adjusted in consideration of the warpage property of the semiconductor package, and the warpage in the semiconductor package may be suppressed. For example, the package substrate 100, which is provided as a lower part of the semiconductor package, may be configured to have a thermal expansion coefficient that is substantially equal or similar to that of that of the device layer DL, which is provided as an upper part of the semiconductor package. Although the package substrate 100 differs from the first and second semiconductor chips 500 and 600 in terms of the constituent materials used, by adjusting the material of the second mold layer 320, a difference in thermal expansion coefficient between the package substrate 100 and the device layer DL may be reduced. As a result, structural and operational stability of the semiconductor package may be improved.

The thermal expansion coefficient of the second mold layer 320 has been described as being smaller than that of the first mold layer 310, but the disclosure is not limited to this example. The second mold layer 320 may be formed of or include a material with a thermal expansion coefficient that is within a range that can suppress warpage in the semiconductor package. In an embodiment, the thermal expansion coefficient of the second mold layer 320 may be greater than the thermal expansion coefficient of the first mold layer 310. In this case, the thermal expansion coefficient of the first mold layer 310 may be smaller than that of the package substrate 100, and the thermal expansion coefficient of the package substrate 100 may be substantially equal or similar to that of the device layer DL including the second mold layer 320. In other words, the thermal expansion coefficient of the second mold layer 320 may be adjusted to reduce warpage, which is caused by a difference in thermal expansion coefficients between the package substrate 100 and the device layer DL. Accordingly, a stress, which is exerted on the semiconductor package when there is the warpage issue, may be reduced, and a contact failure, which may occur in a mounting step of the semiconductor package, may be prevented.

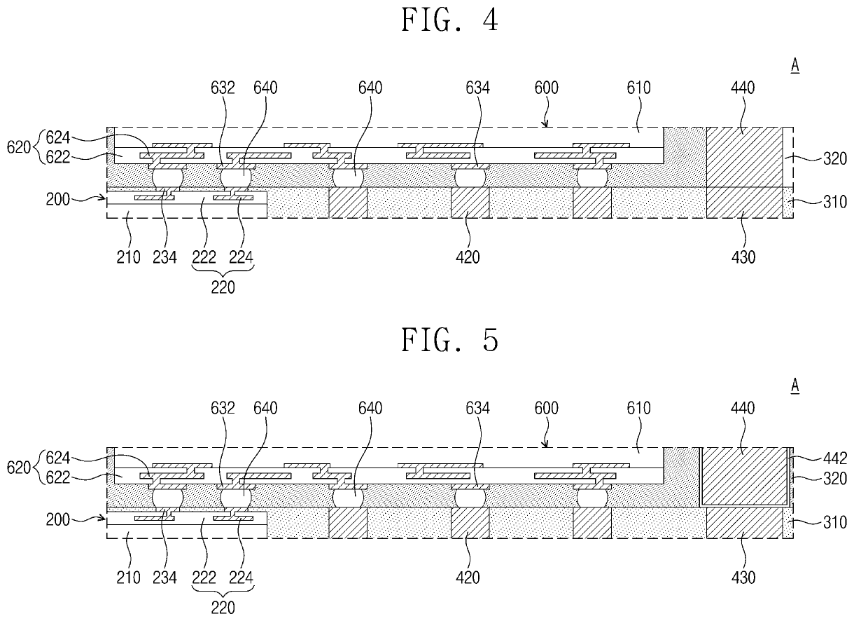

The conductive posts 440 may be disposed on the first mold layer 310. The conductive posts 440 may be disposed in the edge region ER. The conductive posts 440 may be disposed on the third connection pads 430. Each of the conductive posts 440 may contact a top surface of one of the third connection pads 430. The conductive posts 440 may be provided to vertically penetrate the second mold layer 320. For example, the conductive posts 440 may extend toward the package substrate 100 to be coupled to the third connection pads 430 and may extend toward a top surface of the second mold layer 320 to be exposed to the outside of the second mold layer 320 near the top surface of the second mold layer 320. The conductive posts 440 may have a vertically-extended pillar shape. For example, the conductive posts 440 may be a conductive post. However, the disclosure is not limited to this example, and the conductive posts 440 may have various shapes allowing for the vertical connection. Widths of the conductive posts 440 may be smaller than widths of the third connection pads 430. Alternatively, as shown in FIG. 4, the widths of the conductive posts 440 may be substantially equal to the widths of the third connection pads 430. In this case, the conductive posts 440 and the third connection pads 430 may be vertically aligned to each other. Alternatively, as shown in FIG. 5, the widths of the conductive posts 440 may be larger than the widths of the third connection pads 430. In this case, the conductive posts 440 may not contact the third connection pads 430, unlike the embodiment of FIGS. 1 to 4. For example, a seed layer 442 may be further provided to surround or at least partially surround sides surfaces of the conductive posts 440. The seed layer 442 may extend to cover or at least partially cover bottom surfaces of the conductive posts 440. In other words, the conductive posts 440 may be connected to the third connection pads 430 through the seed layer 442 interposed therebetween. The following description will be given based on the embodiment of FIG. 2. Top surfaces of the conductive posts 440 and the top surface of the second mold layer 320 may be located on the same plane. The conductive posts 440 may be formed of or include at least one conductive material. For example, the conductive posts 440 may be formed of or include at least one metallic material (e.g., copper (Cu) or tungsten (W)).

According to an embodiment of the disclosure, the third connection pads 430 and the conductive posts 440 may be provided to vertically penetrate the first mold layer 310 and the second mold layer 320 and may be connected to each other. Thus, the semiconductor package may have efficient heat dissipation characteristics in a vertical direction, and overall heat dissipation characteristics of the semiconductor package may be improved.

Hereinafter, an element previously described with reference to FIGS. 1 to 5 may be identified by the same reference number without repeating description thereof, for convenience in description. That is, technical features, which are different from those in the embodiments of FIGS. 1 to 5, will be mainly described below.

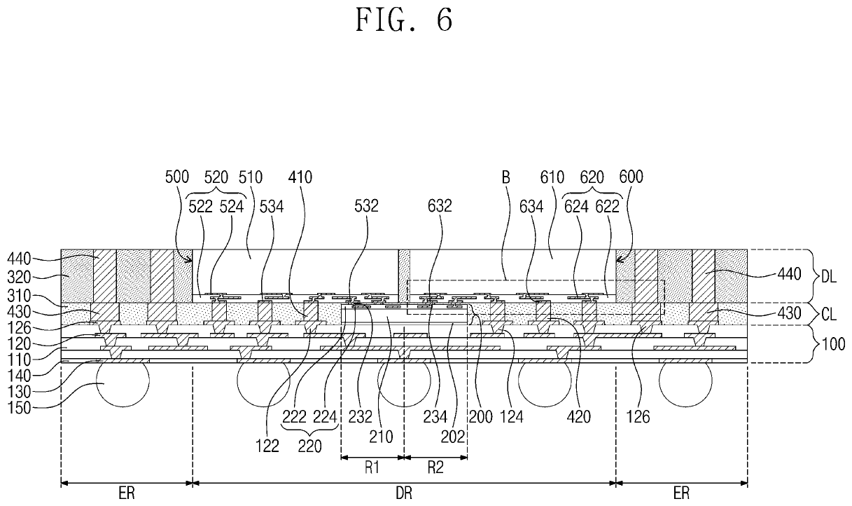

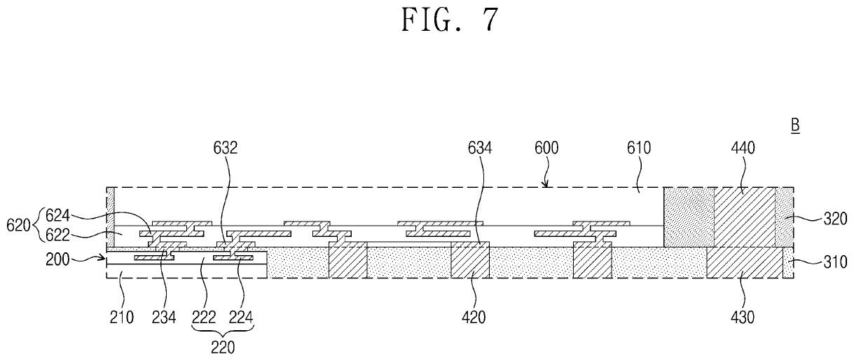

FIG. 6 is a cross-sectional view illustrating a semiconductor package according to an embodiment of the disclosure. FIG. 7 is an enlarged cross-sectional view illustrating a portion ‘B’ of FIG. 6 according to an embodiment.

Referring to FIGS. 6 and 7, a semiconductor package may not include the first and second connection terminals 540 and 640.

The first mold layer 310 may be provided on the package substrate 100. The first mold layer 310 on the package substrate 100 may be provided to surround or at least partially surround the bridge chip 200 and first to the third connection pads 430. The top surface of the first mold layer 310, the top surfaces of the first and second bridge chip pads 232 and 234, and the top surfaces of the first to third connection pads 410, 420, and 430 may be substantially flat and may be substantially coplanar with each other. The first mold layer 310 may be formed of or include at least one insulating material (e.g., silicon oxide (SiO), silicon nitride (SiN), and silicon oxynitride (SiON)).

The first and second semiconductor chips 500 and 600 may contact the top surface of the first mold layer 310. The bottom surface of the first semiconductor chip 500 may contact the top surface of the first mold layer 310, the top surfaces of the first connection pads 410, and the top surface on the first region RI of the bridge chip 200, and the second semiconductor chip 600 may contact the top surface of the first mold layer 310, the top surfaces of the second connection pads 420, and the top surface on the second region R2 of the bridge chip 200. The first semiconductor chip pads 532 of the first semiconductor chip 500 may contact the first bridge chip pads 232 of the bridge chip 200. The second semiconductor chip pads 534 of the first semiconductor chip 500 may contact the first connection pads 410. The third semiconductor chip pads 632 of the second semiconductor chip 600 may contact the second bridge chip pads 234 of the bridge chip 200. The fourth semiconductor chip pads 634 of the second semiconductor chip 600 may contact the second connection pads 420. Since the first and second semiconductor chips 500 and 600 contact the first mold layer 310, the second mold layer 320 may not be interposed between the first and second semiconductor chips 500 and 600 and the first mold layer 310. The bottom surfaces of the first and second semiconductor chips 500 and 600 may be coplanar with a bottom surface of the second mold layer 320.

The first semiconductor chip 500 may be mounted on the bridge chip 200 and the first connection pads 410. The first semiconductor chip pads 532 may be directly connected to the first bridge chip pads 232, and the second semiconductor chip pads 534 may be directly connected to the first connection pads 410. For example, the first semiconductor chip pads 532 and the first bridge chip pads 232 as well as the second semiconductor chip pads 534 and the first connection pads 410 may be provided to form inter-metal hybrid bonding structures. The hybrid bonding structure may refer to a bonding structure which is formed by two materials, which are of the same kind and are fused at an interface therebetween. For example, the first semiconductor chip pads 532 and the first bridge chip pads 232, which are bonded to each other, and the second semiconductor chip pads 534 and the first connection pads 410, which are bonded to each other, may be provided to form a continuous structure, and thus, there may be no observable interface therebetween. For example, the first semiconductor chip pads 532 and the first bridge chip pads 232 may be formed of the same material to serve as a single element. The second semiconductor chip pads 534 and the first connection pads 410 may be formed of the same material to serve as a single element. In other words, the first semiconductor chip pads 532 and the first bridge chip pads 232 may be bonded to form a single object, and the second semiconductor chip pads 534 and the first connection pads 410 may be bonded to form a single object.

The second semiconductor chip 600 may be mounted on the bridge chip 200 and the second connection pads 420. The third semiconductor chip pads 632 may be directly connected to the second bridge chip pads 234, and the fourth semiconductor chip pads 634 may be directly connected to the second connection pads 420. For example, the third semiconductor chip pads 632 and the second bridge chip pads 234 as well as the fourth semiconductor chip pads 634 and the second connection pads 420 may be provided to form inter-metal hybrid bonding structures. For example, the third semiconductor chip pads 632 and the second bridge chip pads 234, which are bonded to each other, and the fourth semiconductor chip pads 634 and the second connection pads 420, which are bonded to each other, may be provided to form a continuous structure, and thus, there may be no observable interface therebetween. For example, the third semiconductor chip pads 632 and the second bridge chip pads 234 may be formed of the same material to serve as a single element. The fourth semiconductor chip pads 634 and the second connection pads 420 may be formed of the same material to serve as a single element. In other words, the third semiconductor chip pads 632 and the second bridge chip pads 234 may be bonded to form a single object, and the fourth semiconductor chip pads 634 and the second connection pads 420 may be bonded to form a single object.

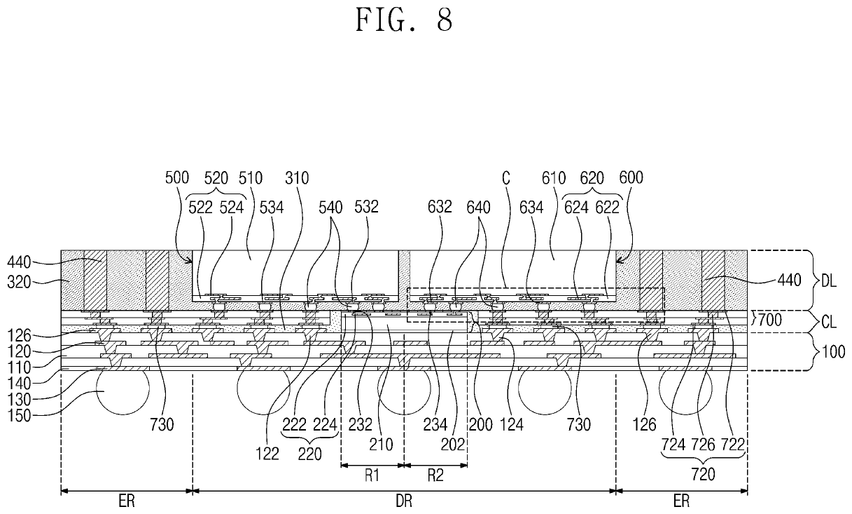

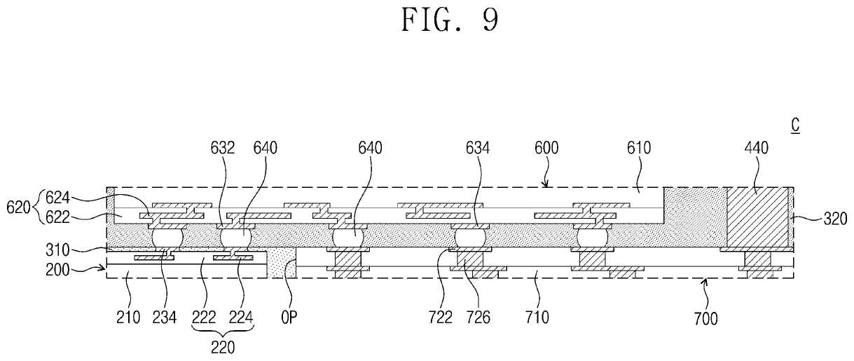

FIG. 8 is a cross-sectional view illustrating a semiconductor package according to an embodiment of the disclosure. FIG. 9 is an enlarged cross-sectional view illustrating a portion ‘C’ of FIG. 8 according to an embodiment.

Referring to FIGS. 8 and 9, a semiconductor package may include a connection substrate 700, which is provided instead of the first to third connection pads 410, 420, and 430 (e.g., of FIG. 1). The connection substrate 700 may be disposed on the package substrate 100. An opening OP may be provided to penetrate the connection substrate 700. For example, the opening OP may have an opened-hole shape that extends from the top surface of the connection substrate 700 to the bottom surface. The opening OP may be placed on the mounting region DR of the package substrate 100. The connection substrate 700 may be disposed around the bridge chip 200 and may include vertical connection terminals, which are connected to the package substrate 100.

The connection substrate 700 may include a base layer 710 and a conductive portion 720, which is an interconnection pattern provided in the base layer 710. In an embodiment, the base layer 710 may be formed of or include silicon oxide (SiO). The conductive portion 720 may be disposed in an outer portion of the connection substrate 700 spaced apart from the opening OP.

The conductive portion 720 may include upper pads 722, vias 726, and lower pads 724. The upper pads 722 may be disposed in an upper portion of the connection substrate 700. The upper pads 722 may be exposed to the outside of the connection substrate 700, near the top surface of the connection substrate 700. The lower pads 724 may be disposed in a lower portion of the connection substrate 700. The lower pads 724 may be exposed to the outside of the connection substrate 700, near the bottom surface of the connection substrate 700. The vias 726 may be provided to penetrate the base layer 710 and may be used as penetration electrodes electrically connecting the upper pads 722 to the lower pads 724.

The connection substrate 700 may be mounted on the package substrate 100. In an embodiment, connection substrate terminals 730 may be provided on the lower pads 724 of the connection substrate 700. The connection substrate terminals 730 may be coupled to the first to third substrate pads 122, 124, and 126 of the package substrate 100.

The bridge chip 200 may be disposed in the opening OP of the connection substrate 700. The bridge chip 200 may have a planar area smaller than the opening OP, in a plan view. In other words, the bridge chip 200 may be spaced apart from an inner surface of the opening OP.

The first mold layer 310 may fill a space between the connection substrate 700 and the bridge chip 200. In other words, the first mold layer 310 may fill a remaining portion of the opening OP of the connection substrate 700. The first mold layer 310 may be provided to fill a space between the package substrate 100 and the connection substrate 700 and surround or at least partially surround the connection substrate terminals 730. The top surface of the first mold layer 310 may be coplanar with the top surface of the connection substrate 700.

The first and second semiconductor chips 500 and 600 may be mounted on the bridge chip 200 and the connection substrate 700. For example, the first semiconductor chip 500 may be connected to the first bridge chip pads 232 of the bridge chip 200 and the upper pads 722 of the connection substrate 700 using the first connection terminals 540. The second semiconductor chip 600 may be connected to the second bridge chip pads 234 of the bridge chip 200 and the upper pads 722 of the connection substrate 700 using the second connection terminals 640. The conductive posts 440 may be connected to the upper pads 722 of the connection substrate 700, on the edge region ER.

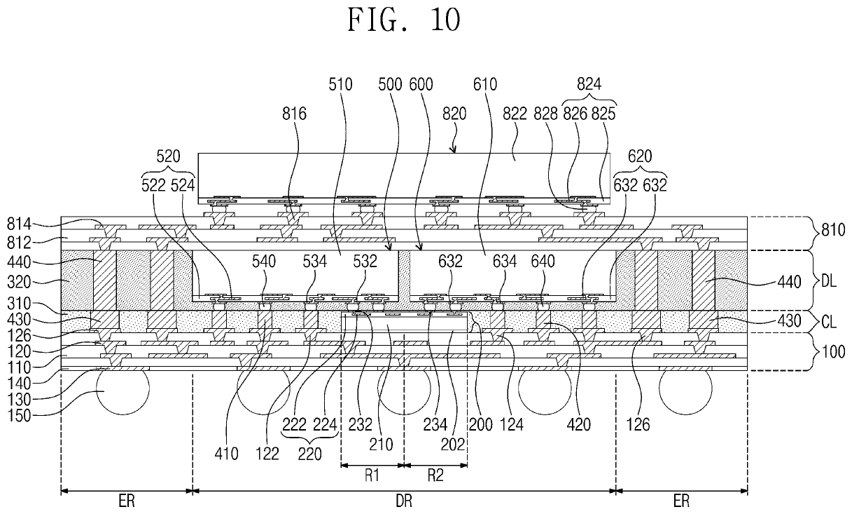

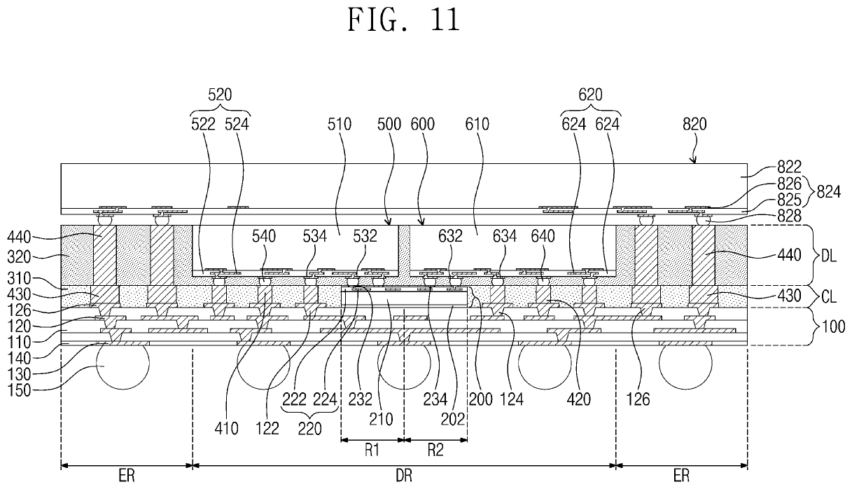

FIGS. 10 and 11 are cross-sectional views each illustrating a semiconductor package according to an embodiment of the disclosure.

Referring to FIG. 10, a semiconductor package may further include a redistribution layer 810 and a third semiconductor chip 820.

The redistribution layer 810 may be disposed on the second mold layer 320. The redistribution layer 810 may include one or more second substrate interconnection layers, which may be sequentially stacked. Each of the second substrate interconnection layers may include a second substrate insulating pattern 812 and a second substrate interconnection pattern 814 in the second substrate insulating pattern 812. The second substrate interconnection pattern 814 of one of the second substrate interconnection layers may be electrically connected to the second substrate interconnection pattern 814 of a neighboring one of the second substrate interconnection layers.

The second substrate insulating pattern 812 may cover or at least partially cover the second mold layer 320, the conductive posts 440, the first semiconductor chip 500, and the second semiconductor chip 600. The second substrate insulating pattern 812 may be formed of or include at least one of insulating polymers or photoimageable polymers (e.g., photoimageable dielectric (PID) materials). Alternatively, the second substrate insulating pattern 812 may be formed of or include at least one insulating material.

The second substrate interconnection pattern 814 may be provided on the second substrate insulating pattern 812. The second substrate interconnection pattern 814 may be horizontally extended, on the second substrate insulating pattern 812. The second substrate interconnection pattern 814 may be provided on a top surface of the second substrate insulating pattern 812. The second substrate interconnection pattern 814 may extend to a level higher than the top surface of the second substrate insulating pattern 812. The second substrate interconnection pattern 814 on the second substrate insulating pattern 812 may be covered or at least partially covered with another second substrate insulating pattern 812 thereon. The second substrate interconnection pattern 814, which is provided in the uppermost one of the second substrate interconnection layers, may be used as fourth substrate pads 816 coupled to third semiconductor chip 820. As described above, the second substrate interconnection pattern 814 may serve as a pad portion or a wire portion of the second substrate interconnection layer. In other words, the second substrate interconnection pattern 814 may be an element for horizontal redistribution of the redistribution layer 810. The second substrate interconnection pattern 814 may be formed of or include at least one conductive material.

The second substrate interconnection pattern 814 may have a damascene structure. For example, the second substrate interconnection pattern 814 may include a via portion extended toward a bottom surface thereof. The via portion may be configured to vertically connect the second substrate interconnection patterns 814 (which are included in adjacent ones of the second substrate interconnection layers) to each other. For example, the via portion may extend from a bottom surface of the second substrate interconnection pattern 814 to penetrate the second substrate insulating pattern 812 and may be coupled to a top surface of the second substrate interconnection pattern 814 of another second substrate interconnection layer thereunder. In an embodiment, the via portion may be configured to connect the second substrate interconnection pattern 814 of the lowermost one of the second substrate interconnection layers to the conductive posts 440. For example, the via portion may extend from the bottom surface of the second substrate interconnection pattern 814 to penetrate the lowermost one of the second substrate insulating patterns 812 and may be coupled to the top surfaces of the conductive posts 440. In other words, an upper portion of the second substrate interconnection pattern 814, which is placed on the second substrate insulating pattern 812, may be a head portion serving as a horizontal wire or a pad, and the via portion of the second substrate interconnection pattern 814 may be a tail portion. The second substrate interconnection pattern 814 may be a ‘T’-shaped pattern.

The third semiconductor chip 820 may be disposed on the redistribution layer 810. The third semiconductor chip 820 may include a third chip base layer 822 and a third chip interconnection layer 824.

The third chip base layer 822 may include a semiconductor substrate. For example, the third chip base layer 822 may be a semiconductor substrate (e.g., a semiconductor wafer). A third integrated circuit may be provided on a bottom surface of the third chip base layer 822. The third integrated circuit may include a logic circuit or a memory circuit. For example, the third semiconductor chip 820 may be a logic chip or a memory chip. A bottom surface of the third semiconductor chip 820 may be an active surface, and a top surface of the third semiconductor chip 820 may be an inactive surface. In an embodiment, the third semiconductor chip 820 may be disposed on the second mold layer 320 in a face-down manner.

The third chip interconnection layer 824 may be disposed on the bottom surface of the third chip base layer 822. For example, the third chip interconnection layer 824 may include a third chip insulating pattern 825 and a third chip interconnection pattern 826 formed on the bottom surface of the third chip base layer 822. The third chip interconnection layer 824 may further include a circuit pattern or a protection layer, if necessary.

The third chip insulating pattern 825 may be disposed on the bottom surface of the third chip base layer 822 to cover or at least partially cover the third integrated circuit. The third chip base layer 822 may be formed of or include at least one insulating material.

The third chip interconnection pattern 826 may be provided in the third chip insulating pattern 825. The third chip interconnection pattern 826 may be electrically connected to the third integrated circuit, which is formed on the bottom surface of the third chip base layer 822. The third chip interconnection pattern 826 may be formed of or include at least one conductive material. Portions of the third chip interconnection pattern 826, which is exposed to the outside of the third chip interconnection layer 824 near a bottom surface of the third chip interconnection layer 824, may serve as chip pads of the third semiconductor chip 820.

The third semiconductor chip 820 may be mounted on the redistribution layer 810. For example, the third semiconductor chip 820 may be mounted on the redistribution layer 810 in a flip-chip manner. The third semiconductor chip 820 may be electrically connected to the redistribution layer 810 through third connection terminals 828. The third connection terminals 828 may be provided between the third chip interconnection pattern 826 of the third semiconductor chip 820 and the fourth substrate pads 816 of the redistribution layer 810. The third semiconductor chip 820 may be electrically connected to the conductive posts 440 through the third connection terminals 828 and the redistribution layer 810.

In other embodiments, the semiconductor package may not include the redistribution layer 810. Referring to FIG. 11, the third semiconductor chip 820 may be disposed on the second mold layer 320.

The third semiconductor chip 820 may be mounted on the conductive posts 440. For example, the third semiconductor chip 820 may be mounted on the conductive posts 440 in a flip-chip manner. The third semiconductor chip 820 may be electrically connected to the conductive posts 440 through the third connection terminals 828. The third connection terminals 828 may be provided between the third chip interconnection pattern 826 of the third semiconductor chip 820 and the conductive posts 440.

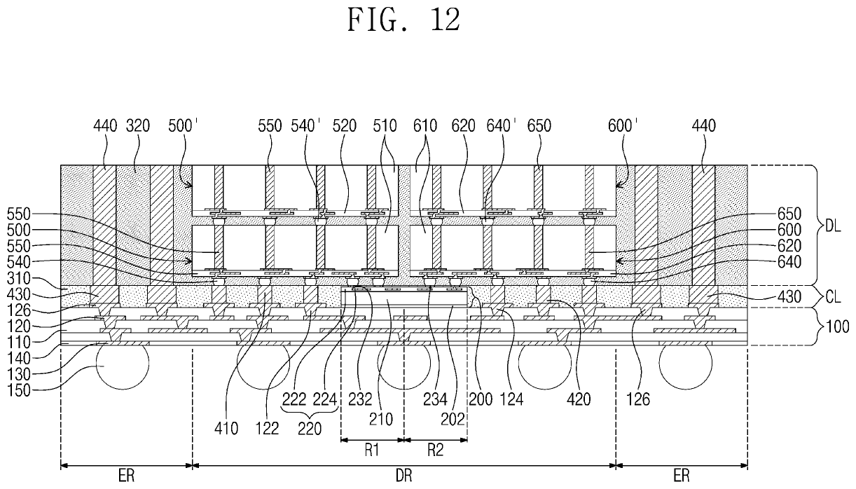

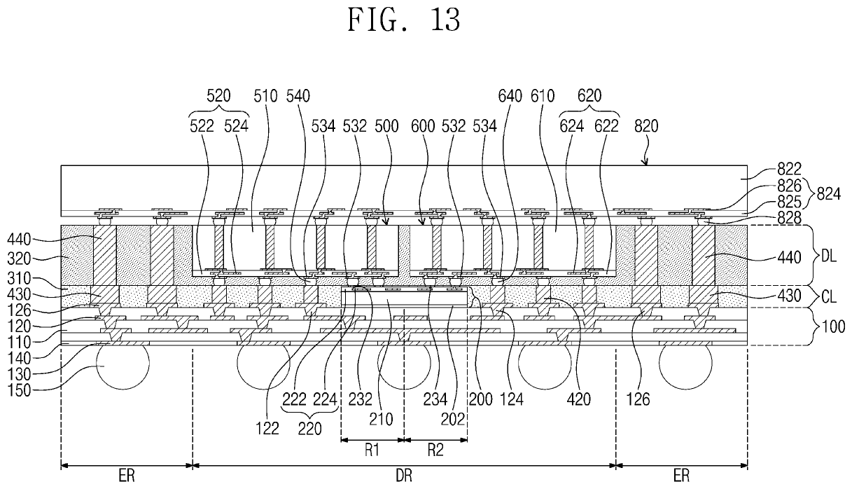

FIGS. 12 and 13 are cross-sectional views each illustrating a semiconductor package according to an embodiment of the disclosure.

Referring to FIG. 12, the first and second semiconductor chips 500 and 600 may further include chip via portions. The first semiconductor chip 500 may further include first chip vias 550, which are provided to vertically penetrate the first chip base layer 510 and are connected to the first integrated circuit or the first chip interconnection layer 520 of the first semiconductor chip 500. The first chip vias 550 may be exposed through the rear surface of the first semiconductor chip 500 (i.e., the top surface of the first chip base layer 510). The second semiconductor chip 600 may further include second chip vias 650, which are provided to vertically penetrate the second chip base layer 610 and are connected to the second integrated circuit or the second chip interconnection layer 620 of the second semiconductor chip 600. The second chip vias 650 may be exposed through the rear surface of the second semiconductor chip 600 (i.e., the top surface of the second chip base layer 610). The first and second chip vias 550 and 650 may be formed of or include at least one conductive material. For example, the first and second chip vias 550 and 650 may be formed of or include at least one metallic material (e.g., copper (Cu) or tungsten (W)).

In an embodiment, the semiconductor package may include a plurality of first semiconductor chips and a plurality of second semiconductor chips. For example, an upper first semiconductor chip 500′ may be vertically stacked on a lower first semiconductor chip 500, and an upper second semiconductor chip 600′ may be vertically stacked on a lower second semiconductor chip 600.

The lower first semiconductor chip 500 may be mounted on the bridge chip 200 and the first connection pads 410. The upper first semiconductor chip 500′ may be mounted on the lower first semiconductor chip 500. For example, the upper first semiconductor chip 500′ may be mounted on the lower first semiconductor chip 500 using first connection terminals 540′, which are coupled to the first chip interconnection pattern 524 of the first chip interconnection layer 520. The first connection terminals 540′ may connect the first chip vias 550 of the lower first semiconductor chip 500 to the first chip interconnection pattern 524 of the upper first semiconductor chip 500′.

The lower second semiconductor chip 600 may be mounted on the bridge chip 200 and the second connection pads 420. The upper second semiconductor chip 600′ may be mounted on the lower second semiconductor chip 600. For example, the upper second semiconductor chip 600′ may be mounted on the lower second semiconductor chip 600 using second connection terminals 640′, which are coupled to the second chip interconnection pattern 624 of the second chip interconnection layer 620. The second connection terminals 640′ may connect the second chip vias 650 of the lower second semiconductor chip 600 to the second chip interconnection pattern 624 of the upper second semiconductor chip 600′.

The second mold layer 320 may be provided to surround or at least partially surround the first and second semiconductor chips 500, 500′, 600, and 600′. A top surface of the upper first semiconductor chip 500′ and a top surface of the upper second semiconductor chip 600′ may be coplanar with the top surface of the second mold layer 320.

FIG. 12 illustrates an example, in which two first semiconductor chips 500 and 500′ and two the second semiconductor chips 600 and 600′ are provided, but the disclosure is not limited to this example. In an embodiment, the semiconductor package may be configured to include one first semiconductor chip 500 with the chip vias 550 and one second semiconductor chip 600 with the chip vias 650 or to include three or more first semiconductor chips 500 and 500′ with the chip vias 550 and three or more second semiconductor chips 600 and 600′ with the chip vias 650.

In an embodiment, the third semiconductor chip 820 may be further provided on the package of FIG. 12. For brevity, the following description of FIG. 13 may refer to an embodiment with one first semiconductor chip 500 with the chip vias 550 and one second semiconductor chip 600 with the chip vias 650.

Referring to FIG. 13, the third semiconductor chip 820 may be disposed on the second mold layer 320.

The third semiconductor chip 820 may be mounted on the first semiconductor chip 500, the second semiconductor chip 600, and the conductive posts 440. For example, the third semiconductor chip 820 may be mounted on the first semiconductor chip 500, the second semiconductor chip 600, and the conductive posts 440 in a flip-chip manner. The third semiconductor chip 820 may be electrically connected to the first chip vias 550 of the first semiconductor chip 500, the second chip vias 650 of the second semiconductor chip 600, and the conductive posts 440 through the third connection terminals 828. The third connection terminals 828 may be provided between the third chip interconnection pattern 826 of the third semiconductor chip 820 and the conductive posts 440, between the third chip interconnection pattern 826 and the first chip vias 550, and between the third chip interconnection pattern 826 and the second chip vias 650.

In an embodiment, the semiconductor package may be configured to include two or more first semiconductor chips 500 with the chip vias 550 and two or more second semiconductor chips 600 with the chip vias 650.

FIG. 13 illustrates an example, in which the third semiconductor chip 820 is mounted on the second mold layer 320, but the disclosure is not limited to this example. In other embodiments, the redistribution layer 810 may be mounted on the second mold layer 320.

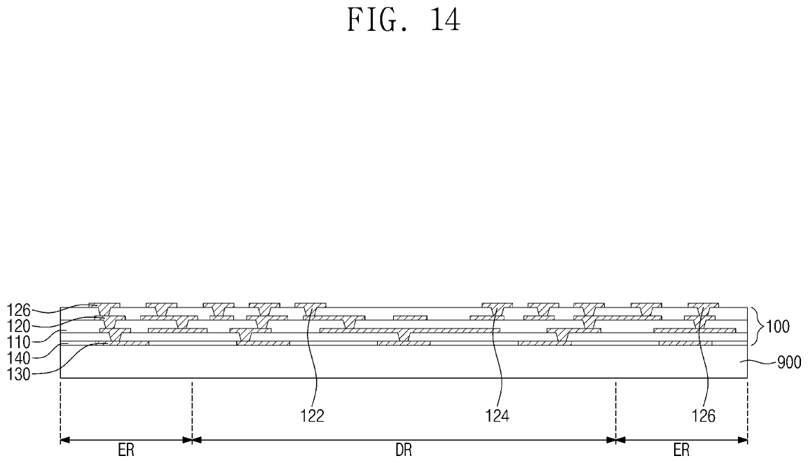

FIGS. 14 to 21 are cross-sectional views illustrating a method of fabricating a semiconductor package, according to an embodiment of the disclosure.

Referring to FIG. 14, a carrier substrate 900 may be provided. The carrier substrate 900 may be an insulating substrate, which is formed of or includes glass or polymer, or a conductive substrate, which is formed of or includes a metallic material. An adhesive member may be provided on a top surface of the carrier substrate 900. As an example, the adhesive member may include an adhesive tape.

The package substrate 100 may be formed on the carrier substrate 900.

The substrate protection layer 140 may be provided on the carrier substrate 900. The substrate protection layer 140 may be formed by a deposition process or a coating process. The outer pads 130 may be formed in the substrate protection layer 140. For example, the formation of the outer pads 130 may include patterning the substrate protection layer 140 to form openings for the outer pads 130, forming a seed layer to conformally cover the openings, and performing a plating process using the seed layer to fill the openings with a conductive material.

The first substrate insulating pattern 110 may be formed on the substrate protection layer 140. The first substrate insulating pattern 110 may be formed by a deposition process or a coating process. The first substrate interconnection pattern 120 may be formed on the first substrate insulating pattern 110. For example, the formation of the first substrate interconnection pattern 120 may include patterning the first substrate insulating pattern 110 to form openings exposing the outer pads 130, forming a seed layer to conformally cover the top surface of the first substrate insulating pattern 110 and the openings, performing a plating process using the seed layer to form a conductive layer covering or at least partially covering the first substrate insulating pattern 110 and filling the openings, and patterning the conductive layer to form the first substrate interconnection pattern 120 coupled to the outer pads 130.

As a result of the above process, one first substrate interconnection layer, which may include the first substrate insulating pattern 110 and the first substrate interconnection pattern 120 therein, may be formed on the substrate protection layer 140 and the outer pads 130. In an embodiment, the process of forming the first substrate interconnection layer may be repeated to fabricate the package substrate 100. The package substrate 100 may have the mounting region DR and the edge region ER. The first substrate interconnection pattern 120, which is provided in the uppermost one of the first substrate interconnection layers, may serve as the first to third substrate pads 122, 124, and 126, which will be described again below.

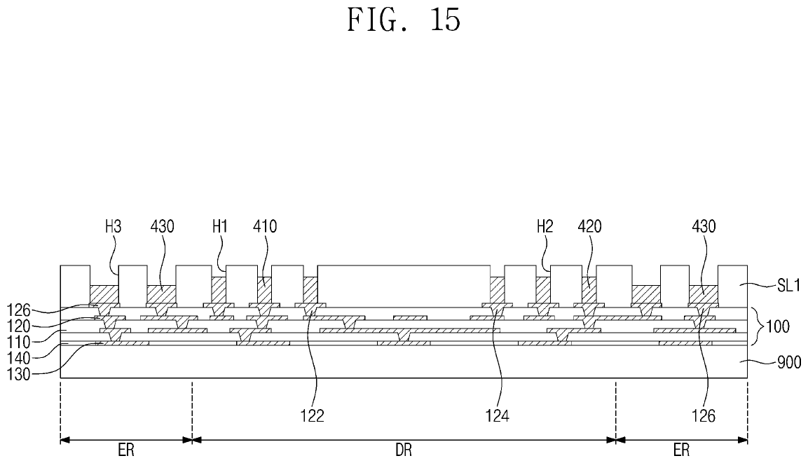

Referring to FIG. 15, a first sacrificial layer SL1 may be formed on the package substrate 100. The first sacrificial layer SL1 may cover or at least partially cover the top surface of the package substrate 100. The first sacrificial layer SL1 may be patterned to form first holes H1 exposing the first substrate pads 122, second holes H2 exposing the second substrate pads 124, and third holes H3 exposing the third substrate pads 126. Widths of the first and second holes H1 and H2 may be smaller than widths of the third holes H3, and a distance between the first holes H1 and a distance between the second holes H2 may be smaller than a distance between the third holes H3.

Thereafter, the first to third connection pads 410, 420, and 430 may be formed by filling the first to third holes H1, H2, and H3 with a conductive material. For example, the first to third connection pads 410, 420, and 430 may be formed by performing a plating process using top surfaces of the first to third substrate pads 122, 124, and 126, which are exposed through the first to third holes H1, H2, and H3, as a seed layer. Since the widths of the first and second holes H1 and H2 are smaller than the widths of the third holes H3, a height of the first and second connection pads 410 and 420 formed in the first and second holes H1 and H2 may be larger than a height of the third connection pads 430 formed in the third holes H3.

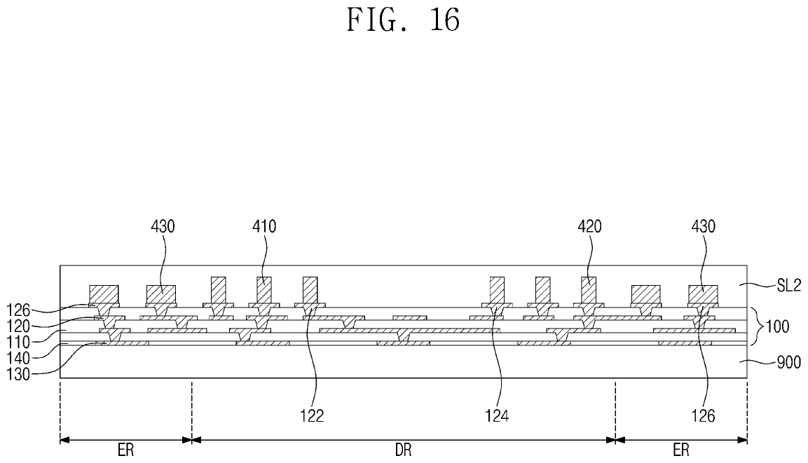

Referring to FIG. 16, the first sacrificial layer SL1 may be removed. Accordingly, the top surface of the package substrate 100 and the first to third connection pads 410, 420, and 430 on the package substrate 100 may be exposed to the outside.

A second sacrificial layer SL2 may be formed on the package substrate 100. The second sacrificial layer SL2 may cover or at least partially cover the top surface of the package substrate 100. In addition, the second sacrificial layer SL2 may be formed to bury the first to third connection pads 410, 420, and 430 on the package substrate 100.

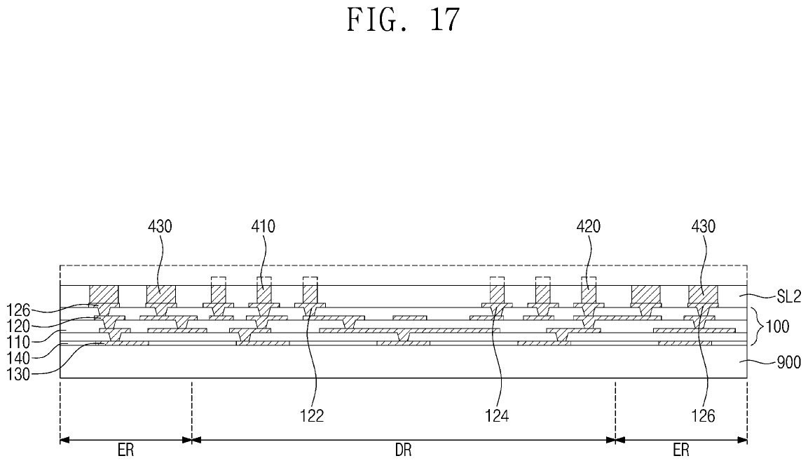

Referring to FIG. 17, a portion of the second sacrificial layer SL2 may be removed. A grinding or chemical mechanical polishing (CMP) process may be performed on a top surface of the second sacrificial layer SL2. The grinding or CMP process may be performed until the top surfaces of the first to third connection pads 410, 420, and 430 are exposed to the outside. Accordingly, a portion of the second sacrificial layer SL2, which is located at a level higher than the top surfaces of the first to third connection pads 410, 420, and 430, may be removed. In an embodiment, upper portions of the first and second connection pads 410 and 420 may be removed during the grinding or CMP process. The grinding or CMP process may be performed until all the top surfaces of the first to third connection pads 410, 420, and 430 are exposed to the outside, and in an embodiment, the upper portions of the first and second connection pads 410 and 420, which are located at a level higher than the third connection pads 430, may be removed. After the grinding or CMP process, the top surface of the second sacrificial layer SL2 and the top surfaces of the first to third connection pads 410, 420, and 430 may be substantially flat and may be substantially coplanar with each other.

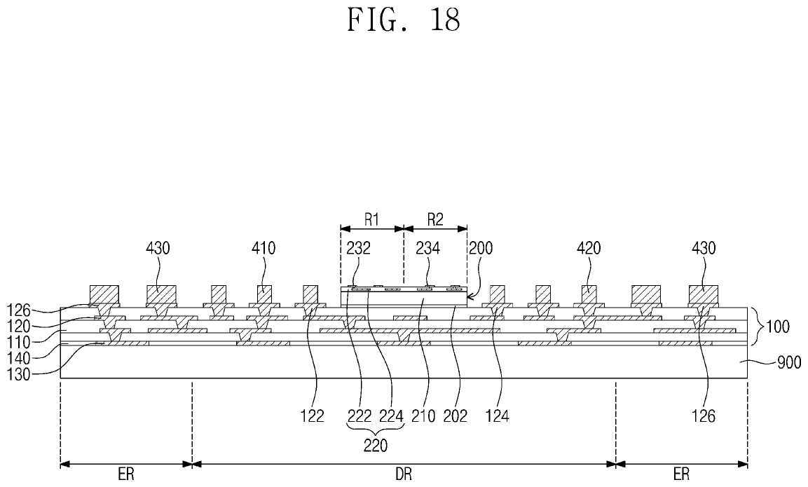

Referring to FIG. 18, the second sacrificial layer SL2 may be removed. Accordingly, the top surface of the package substrate 100 and the first to third connection pads 410, 420, and 430 on the package substrate 100 may be exposed to the outside.

The bridge chip 200 may be attached to the package substrate 100. The bridge chip 200 may have substantially the same or similar features as that in the embodiments of FIGS. 1 to 13. The bridge chip 200 may be attached to the package substrate 100 using the adhesive layer 202.

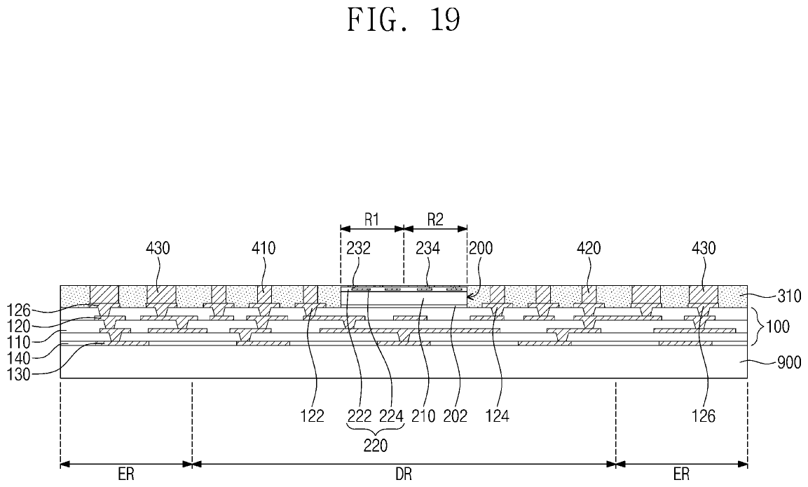

Referring to FIG. 19, the first mold layer 310 may be formed on the package substrate 100. For example, the formation of the first mold layer 310 may include depositing or coating an insulating layer on the package substrate 100 to cover or at least partially cover the bridge chip 200 and the first to third connection pads 410, 420, and 430 and curing the insulating layer. Thereafter, a thinning process may be performed on the first mold layer 310. Accordingly, the top surfaces of the first to third connection pads 410, 420, and 430 and the top surfaces of the first and second bridge chip pads 232 and 234 of the bridge chip 200 may be exposed to the outside. The first mold layer 310 may be formed of or include an insulating polymer material (e.g., an EMC).

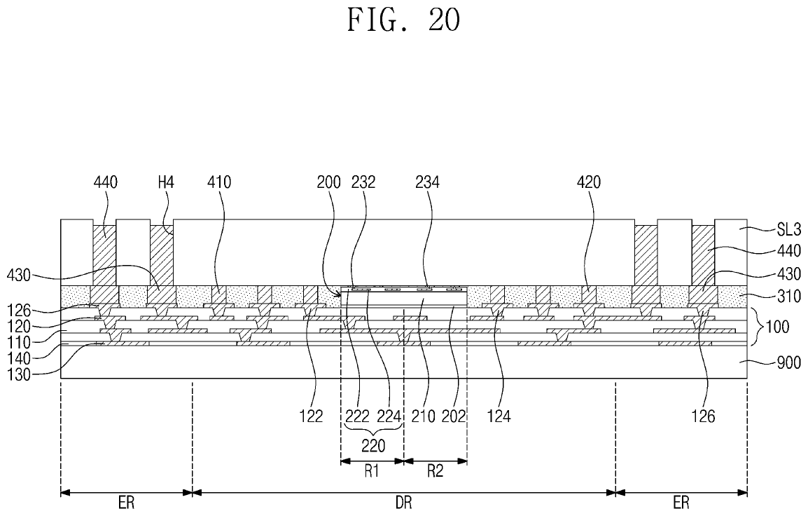

Referring to FIG. 20, a third sacrificial layer SL3 may be formed on the first mold layer 310. The third sacrificial layer SL3 may cover or at least partially cover the first mold layer 310, the first to third connection pads 410, 420, and 430, and the bridge chip 200. The third sacrificial layer SL3 may be patterned to form fourth holes H4 exposing the third connection pads 430.

The conductive posts 440 may be formed by filling the fourth holes H4 with a conductive material. For example, the conductive posts 440 may be formed by performing a plating process using the top surfaces of the third connection pads 430, which are exposed through the fourth holes H4, as a seed layer.

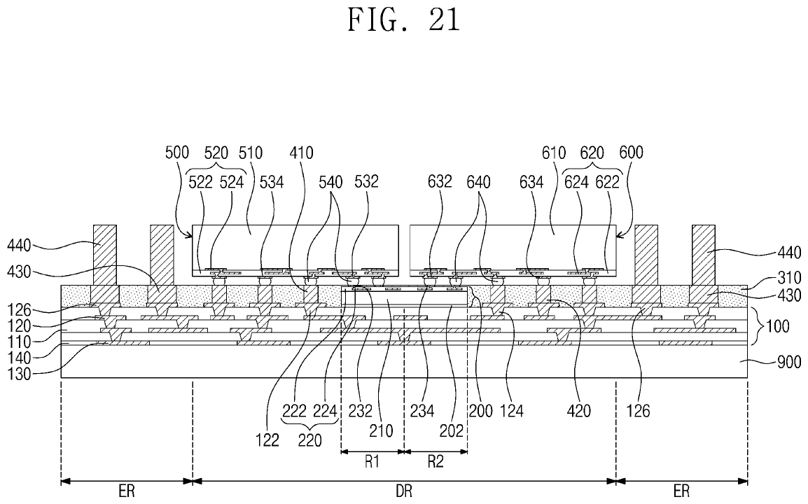

Referring to FIG. 21, the third sacrificial layer SL3 may be removed. Accordingly, the top surface of the first mold layer 310, the top surfaces of the first and second connection pads 410 and 420, the top surfaces of the first and second bridge chip pads 232 and 234, and the conductive posts 440 on the first mold layer 310 may be exposed to the outside.

The first and second semiconductor chips 500 and 600 may be mounted on the first and second connection pads 410 and 420 and the bridge chip 200. The first and second semiconductor chips 500 and 600 may have substantially the same or similar features as those in the embodiments of FIGS. 1 to 13. The first and second semiconductor chips 500 and 600 may be mounted in a flip-chip manner. For example, the first connection terminals 540 may be provided on the first and second semiconductor chip pads 532 and 534 of the first semiconductor chip 500, and the second connection terminals 640 may be provided on the third and fourth semiconductor chip pads 632 and 634 of the second semiconductor chip 600. The first and second semiconductor chips 500 and 600 may be aligned to the first mold layer 310 such that the first connection terminals 540 are placed on the first bridge chip pads 232 of the bridge chip 200 and the first connection pads 410 and that the second connection terminals 640 are placed on the second bridge chip pads 234 of the bridge chip 200 and the second connection pads 420. Thereafter, a reflow process may be performed to bond the first connection terminals 540 to the first bridge chip pads 232 and the first connection pads 410 and bond the second connection terminals 640 to the second bridge chip pads 234 and the second connection pads 420.

Referring back to FIG. 1, the second mold layer 320 may be formed on the first mold layer 310. For example, the formation of the second mold layer 320 may include depositing or coating an insulating layer on the first mold layer 310 to cover or at least partially cover the first and second semiconductor chips 500 and 600 and the conductive posts 440 and curing the insulating layer. In an embodiment, a thinning process may be additionally performed on the second mold layer 320. In this case, the top surfaces of the first and second semiconductor chips 500 and 600 and the top surfaces of the conductive posts 440 may be exposed to the outside.

The carrier substrate 900 may be removed. Thus, the substrate protection layer 140 and the outer pads 130 of the package substrate 100 may be exposed to the outside. The outer terminals 150 may be provided on the exposed bottom surfaces of the outer pads 130.

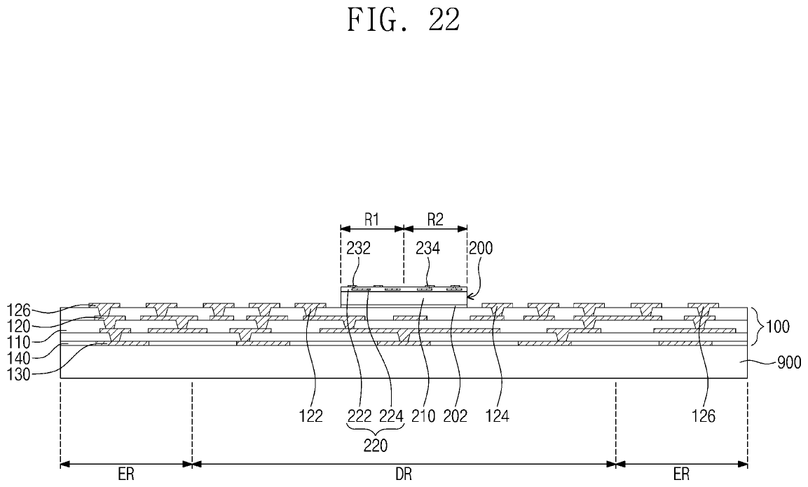

FIGS. 22 to 25 are cross-sectional views illustrating a method of fabricating a semiconductor package, according to an embodiment of the disclosure.

Referring to FIG. 22, the bridge chip 200 may be attached to the package substrate 100 in the resulting structure of FIG. 14. The bridge chip 200 may have substantially the same or similar features as that in the embodiments of FIGS. 1 to 13. The bridge chip 200 may be attached to the mounting region DR of the package substrate 100 using the adhesive layer 202.

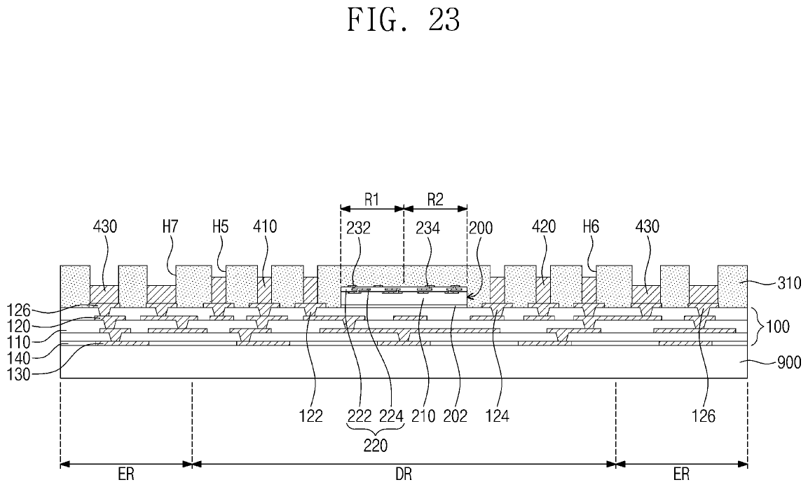

Referring to FIG. 23, the first mold layer 310 may be formed. For example, the first mold layer 310 may be formed by depositing or coating an insulating layer on the package substrate 100 to cover or at least partially cover the bridge chip 200 and curing the insulating layer. The first mold layer 310 may be formed of or include at least one insulating material (e.g., silicon oxide (SiO), silicon nitride (SiN), and silicon oxynitride (SiON)).

The first mold layer 310 may be patterned to form fifth holes H5 exposing the first substrate pads 122, sixth holes H6 exposing the second substrate pads 124, and seventh holes H7 exposing the third substrate pads 126. Widths of the fifth and sixth holes H5 and H6 may be smaller than widths of the seventh holes H7.

The first to third connection pads 410, 420, and 430 may be formed by filling the fifth to seventh holes H5, H6, and H7 with a conductive material. For example, the first to third connection pads 410, 420, and 430 may be formed by performing a plating process using the top surfaces of the first to third substrate pads 122, 124, and 126, which are exposed through the first to third holes H1, H2, and H3, as a seed layer. A height of the first and second connection pads 410 and 420, which are formed in the fifth and sixth holes H5 and H6, may be larger than a height of the third connection pads 430, which are formed in the seventh holes H7.

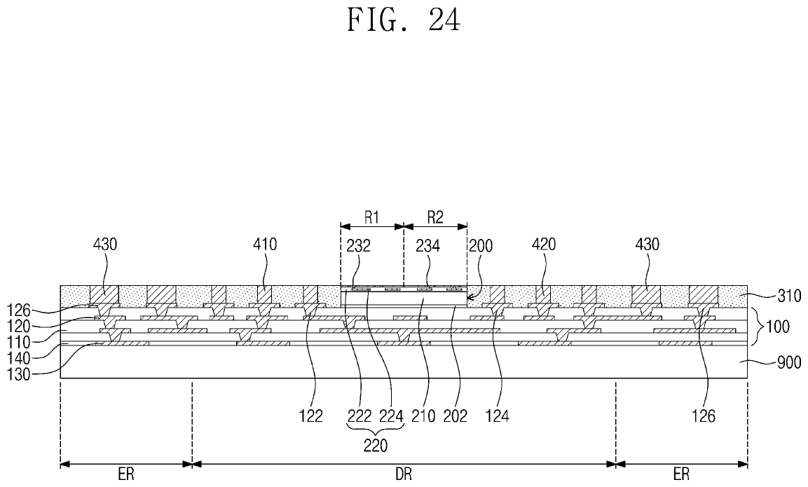

Referring to FIG. 24, a portion of the first mold layer 310 may be removed. A grinding process or a CMP process may be performed on the top surface of the first mold layer 310. The grinding or CMP process may be performed to expose all the top surfaces of the first to third connection pads 410, 420, and 430. For example, upper portions of the first and second connection pads 410 and 420 and a portion of the first mold layer 310, which are placed at a level higher than the third connection pads 430, may be removed by the grinding or CMP process. After the grinding or CMP process, the top surface of the first mold layer 310 and the top surfaces of the first to third connection pads 410, 420, and 430 may be substantially flat and may be substantially coplanar with each other.

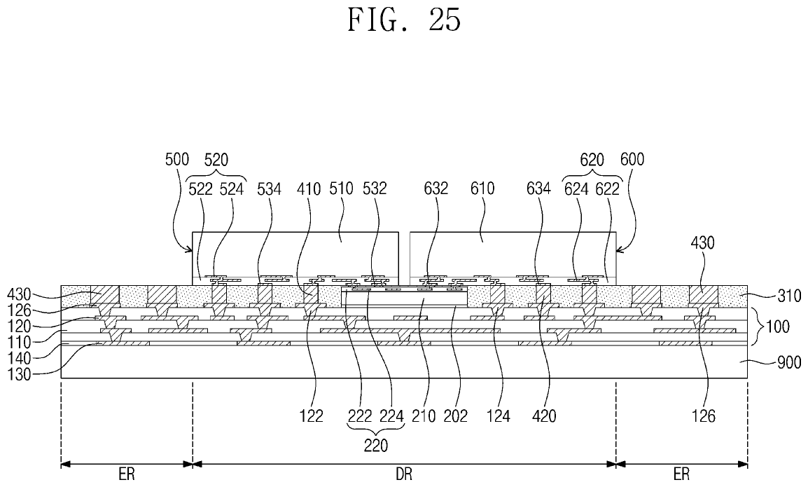

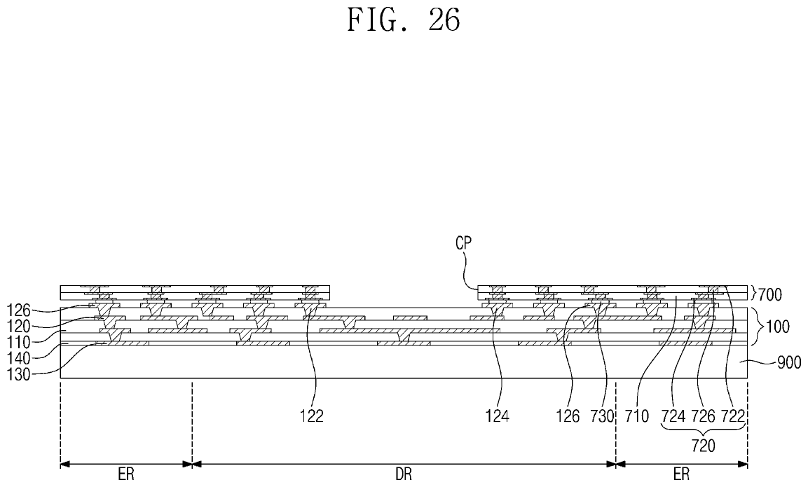

Referring to FIG. 25, the first and second semiconductor chips 500 and 600 may be mounted on the first and second connection pads 410 and 420 and the bridge chip 200. The first and second semiconductor chips 500 and 600 may be aligned to the first mold layer 310 such that the first and second semiconductor chip pads 532 and 534 of the first semiconductor chip 500 are placed on the first bridge chip pads 232 of the bridge chip 200 and the first connection pads 410 and that the third and fourth semiconductor chip pads 632 and 634 of the second semiconductor chip 600 may be placed on the second bridge chip pads 234 of the bridge chip 200 and the second connection pads 420. The first semiconductor chip 500 may be disposed on the first mold layer 310 such that the first semiconductor chip pads 532 contacts the first bridge chip pads 232 and the second semiconductor chip pads 534 contacts the first connection pads 410. The second semiconductor chip 600 may be disposed on the first mold layer 310 such that the third semiconductor chip pads 632 and the fourth semiconductor chip pads 634 contact the second bridge chip pads 234 and the second connection pads 420, respectively. A thermal treatment process may be performed on the first and second semiconductor chips 500 and 600. As a result of the thermal treatment process, the first semiconductor chip pads 532 and the first bridge chip pads 232 may be bonded to each other, the second semiconductor chip pads 534 and the first connection pads 410 may be bonded to each other, the third semiconductor chip pads 632 and the second bridge chip pads 234 may be bonded to each other, and the fourth semiconductor chip pads 634 and the second connection pads 420 may be bonded to each other. For example, the first to fourth semiconductor chip pads 532, 534, 632, and 634 may be bonded to the first bridge chip pads 232, the first connection pads 410, the second bridge chip pads 234, and the second connection pads 420, respectively, to form individual single objects. The bonding between the first to fourth semiconductor chip pads 532, 534, 6232, and 634 and the first and second bridge and connection pads 232, 234, 410, and 420 may be achieved in a natural manner. For example, the first to fourth semiconductor chip pads 532, 534, 632, and 634 and the first and second bridge pads and connection pads 232, 234, 410, and 420 may be formed of the same material (e.g., copper (Cu)), and in this case, the first to fourth semiconductor chip pads 532, 534, 6232, and 634 and the first and second bridge and connection pads 232, 234, 410, and 420 may be bonded to each other by an inter-metal hybrid bonding process caused by a surface activation phenomenon at interfaces therebetween.

Thereafter, the conductive posts 440 may be formed through the process described with reference to FIG. 20, and the second mold layer 320 may be formed through the process described with reference to FIG. 1.

Referring to FIG. 6, the carrier substrate 900 may be removed. The outer terminals 150 may be provided on the exposed bottom surfaces of the outer pads 130.

FIGS. 26 to 28 are cross-sectional views illustrating a method of fabricating a semiconductor package, according to an embodiment of the disclosure.

Referring to FIG. 26, the connection substrate 700 may be mounted on the package substrate 100 in the resulting structure of FIG. 14. The connection substrate 700 may have substantially the same or similar features as that in the embodiments of FIGS. 8 and 9. The connection substrate 700 may be mounted in a flip-chip manner. For example, the connection substrate terminals 730 may be provided on the lower pads 724 of the connection substrate 700. The connection substrate 700 may be aligned to the package substrate 100 such that the connection substrate terminals 730 are placed on the first to third pads 122, 124, and 126 of the package substrate 100. A reflow process may be performed to bond the connection substrate terminals 730 to the first to third pads 122, 124, and 126.

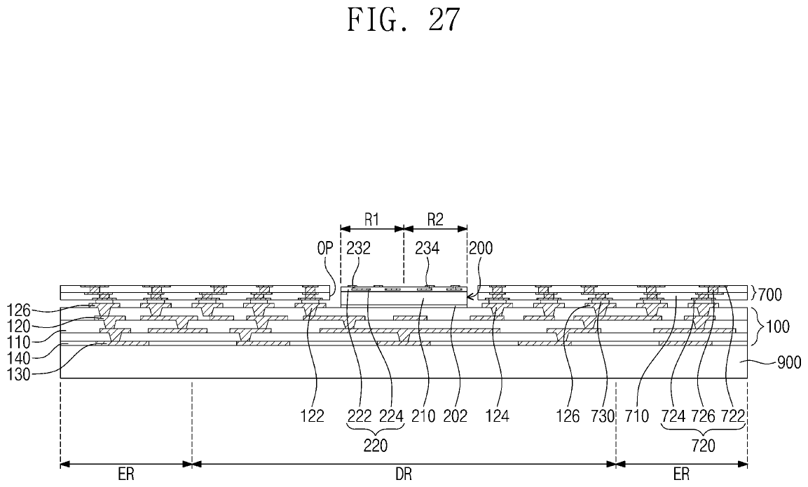

Referring to FIG. 27, the bridge chip 200 may be attached to the package substrate 100. The bridge chip 200 may have substantially the same or similar features as that in the embodiments of FIGS. 1 to 13. The bridge chip 200 may be attached to the package substrate 100 using the adhesive layer 202. The bridge chip 200 may be placed in the opening OP of the connection substrate 700.

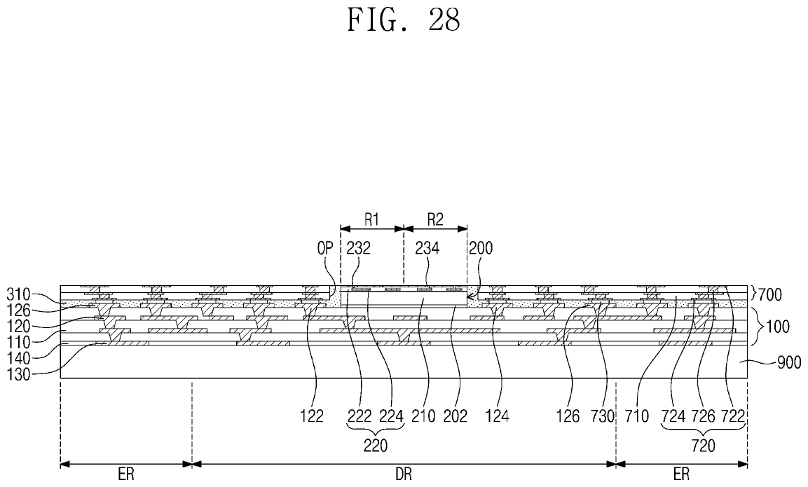

Referring to FIG. 28, the first mold layer 310 may be formed on the package substrate 100. For example, the first mold layer 310 may be formed by depositing or coating an insulating layer on the package substrate 100 to cover or at least partially cover the bridge chip 200 and curing the insulating layer. The insulating layer may be formed to fill a space between the inner side surface of the opening OP of the connection substrate 700 and the bridge chip 200 and a space between the connection substrate 700 and the package substrate 100.

Thereafter, a process, which is the same as or similar to that in FIGS. 20 and 21, may be performed to form the conductive posts 440 as well as the first and second semiconductor chips 500 and 600 on the resulting structure.

Referring to FIG. 8, the carrier substrate 900 may be removed. The outer terminals 150 may be provided on the exposed bottom surfaces of the outer pads 130.

In a semiconductor package according to an embodiment of the disclosure, lengths of electric connection paths between semiconductor chips and a bridge chip and between the semiconductor chips may be reduced. This may improve electrical characteristics of the semiconductor package. In addition, the bridge chip and connection pads may be provided as a single connection layer, using a lower mold layer. This may reduce a thickness of the connection layer and a size of the semiconductor package and to improve structural stability of the semiconductor package.

In addition, a thermal expansion coefficient of an upper mold layer may be adjusted in consideration of a warpage property of the semiconductor package, and thus, warpage in the semiconductor package may be suppressed. As a result, structural and operational stability of the semiconductor package may be improved.

Furthermore, the semiconductor package may be configured to have efficient heat dissipation characteristics in a vertical direction, and overall heat dissipation characteristics of the semiconductor package may be improved.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A semiconductor package, comprising:
a package substrate comprising a mounting region and an edge region at least partially surrounding the mounting region;
a bridge chip on a top surface of the mounting region of the package substrate;
a first connection pad and a second connection pad on the mounting region of the package substrate and spaced apart from the bridge chip;
a third connection pad on the edge region of the package substrate;
a first mold layer on the package substrate and at least partially surrounding the bridge chip, the first connection pad, the second connection pad and the third connection pad;
a first semiconductor chip on the first connection pad and the bridge chip;
a second semiconductor chip on the second connection pad and the bridge chip;
a conductive post on the third connection pad; and
a second mold layer on the first mold layer and at least partially surrounding the first semiconductor chip, the second semiconductor chip and the conductive post,
wherein a first thermal expansion coefficient of the first mold layer is different from a second thermal expansion coefficient of the second mold layer.

2. The semiconductor package of claim 1, wherein the first mold layer contacts the second mold layer.

3. The semiconductor package of claim 1, wherein the bridge chip comprises a first bridge chip pad and a second bridge chip pad,
wherein the first semiconductor chip is mounted on the first connection pad and the first bridge chip pad in a flip chip manner, and
wherein the second semiconductor chip is mounted on the second connection pad and the second bridge chip pad in a flip chip manner.

4. The semiconductor package of claim 3, further comprising:
first connection terminals connecting the first semiconductor chip to the first connection pad and the first bridge chip pad; and
second connection terminals connecting the second semiconductor chip to the second connection pad and the second bridge chip pad,
wherein the first connection terminals and the second connection terminals are in the second mold layer.

5. The semiconductor package of claim 1, further comprising an interface between the first mold layer and the second mold layer,
wherein, on the interface between the first mold layer and the second mold layer,
first semiconductor chip pads of the first semiconductor chip contact the first pad and a first bridge chip pad of the bridge chip, and
second semiconductor chip pads of the second semiconductor chip contact the second pad and a second bridge chip pad of the bridge chip.

6. The semiconductor package of claim 1, wherein a width of the conductive post is smaller than a width of the third connection pad.

7. The semiconductor package of claim 1, wherein widths of the first connection pad and the second pad are smaller than a width of the third connection pad.

8. The semiconductor package of claim 1, wherein an active surface of the bridge chip faces an active surface of the first semiconductor chip and an active surface of the second semiconductor chip.

9. The semiconductor package of claim 1, wherein bridge chip pads of the bridge chip are exposed to an outside of the first mold layer.

10. The semiconductor package of claim 1, wherein the first connection pad, the second connection pad, and the third connection pad vertically penetrate the first mold layer,
wherein the first connection pad, the second connection pad, and the third connection pad are coupled to substrate pads of the package substrate, and
wherein the first connection pad, the second connection pad, and the third connection pad are exposed to an outside of the first mold layer.

11. The semiconductor package of claim 1, further comprising a connection substrate coupled to the package substrate and comprising an opening,
wherein the bridge chip is in the opening of the connection substrate,
wherein the first mold layer is in the opening and at least partially fill a space between the connection substrate and the bridge chip, and
wherein the connection substrate comprises connection substrate upper pads provided on a top surface of the connection substrate, the connection substrate upper pads corresponding to the first connection pad, the second connection pad, and the third connection pad.

12. The semiconductor package of claim 1, further comprising:
a third semiconductor chip on the second mold layer and on a top surface of the conductive post that is exposed to an outside of the second mold layer, or
a redistribution layer on the second mold layer and on the top surface of the conductive post that is exposed to the outside of the second mold layer.

13. The semiconductor package of claim 12, wherein the first semiconductor chip and the second semiconductor chip comprises penetration vias, and
wherein the third semiconductor chip or the redistribution layer is coupled to the conductive post and the penetration vias.

14. A semiconductor package, comprising:
a package substrate;
a bridge chip on the package substrate, the bridge chip comprising at least one first bridge chip pad and at least one second bridge chip pad on a top surface of the bridge chip and horizontally spaced apart;
a first mold layer on the package substrate and at least partially surrounding the bridge chip, wherein the at least one first bridge chip pad and the at least one second bridge chip pad are exposed to an outside of the first mold layer;
a plurality of first connection pads and a plurality of second connection pads horizontally spaced apart from the bridge chip, vertically penetrating the first mold layer, and coupled to the package substrate, the plurality of first connection pads being between the plurality of second connection pads;
a first semiconductor chip on the first mold layer, and on first connection pads of the plurality of first connection pads and the at least one first bridge chip pad;
a second semiconductor chip on the first mold layer, and on second connection pads of the plurality of first connection pads and the at least one second bridge chip pad;
a second mold layer contacting the top surface of the first mold layer and at least partially surrounding the first semiconductor chip and the second semiconductor chip;
a plurality of conductive posts vertically penetrating the second mold layer and respectively coupled to the plurality of second connection pads; and
a plurality of outer terminals below the package substrate,
wherein widths of the plurality of conductive posts are smaller than widths of the plurality of second connection pads.

15. The semiconductor package of claim 14, wherein a first thermal expansion coefficient of the first mold layer is different from a second thermal expansion coefficient of the second mold layer.

16. The semiconductor package of claim 14, wherein the first semiconductor chip is on the first connection pads of the plurality of first connection pads and the at least one first bridge chip pad,
wherein the second semiconductor chip is on the second connection pads of the plurality of first connection pads and the at least one second bridge chip pad, and
wherein the semiconductor package further comprises a plurality of connection terminals in the second mold layer connecting the first semiconductor chip to the first connection pads of the plurality of first connection pads and the at least one first bridge chip pad, and connecting the second semiconductor chip to the second connection pads of the plurality of first connection pads and the at least one second bridge chip pad.

17. The semiconductor package of claim 14, wherein widths of the plurality of first connection pads are smaller than the widths of the plurality of second connection pads.

18. The semiconductor package of claim 14, further comprising an interface between the first mold layer and the second mold layer,
wherein a plurality of first semiconductor chip pads of the first semiconductor chip contact the first connection pads of the plurality of first connection pads and the at least one first bridge chip pad, and
wherein a plurality of second semiconductor chip pads of the second semiconductor chip contact the second connection pads of the plurality of first connection pads and the at least one second bridge chip pad.

19. A semiconductor package, comprising:
a package substrate;
a device layer on the package substrate; and
a connection layer between the package substrate and the device layer,
wherein the device layer comprises:
a first mold layer;
a first semiconductor chip and a second semiconductor chip in the first mold layer;
connection terminals provided on active surfaces of the first semiconductor chip and the second semiconductor chip and exposed to an outside of the first mold layer; and
a conductive post vertically penetrating the first mold layer,
wherein the connection layer comprises:
a second mold layer;
a bridge chip in the second mold layer, wherein each of the first semiconductor chip and the second semiconductor chip are positioned such that the active surfaces at least partially surround the bridge chip in a plan view;
a plurality of first connection pads vertically penetrating the second mold layer and connecting the first semiconductor chip and the second semiconductor chip to the package substrate; and
at least one second connection pad vertically penetrating the second mold layer and connecting the conductive post to the package substrate,
wherein the connection terminals connect the first semiconductor chip and the second semiconductor chip to the bridge chip, and
wherein a first thermal expansion coefficient of the first mold layer is different from a second thermal expansion coefficient of the second mold layer.

20. The semiconductor package of claim 19, wherein a width of the conductive post is smaller than a width of the at least one second connection pad, and
wherein widths of the plurality of first connection pads are smaller than the width of the at least one second connection pad.
